(19) United States
(12) Patent Application Publication
(10) Pub. No.: US 2024/0206228 A1
(43) Pub. Date: Jun. 20, 2024

(54) DISPLAY APPARATUS

(71) Applicant: LG Display Co., Ltd., Seoul (KR)

(72) Inventor: Dojoong KIM, Seoul (KR)

(21) Appl. No.: 18/366,597

(22) Filed: Aug. 7, 2023

(30) Foreign Application Priority Data
Dec. 16, 2022 (KR) 10-2022-0176878

(51) Int. Cl. H10K 59/121; H10K 59/122; H10K 59/123; H10K 59/131; H10K 59/35; H10K 59/80

(52) U.S. Cl. CPC H10K 59/1213; H10K 59/122; H10K 59/123; H10K 59/131; H10K 59/353; H10K 59/80518; H10K 59/878; H10K 59/8792

(57) ABSTRACT

A display apparatus may include a first substrate including a plurality of first sub-pixels and a plurality of second sub-pixels, a first thin film transistor and a second thin film transistor disposed in a first sub-pixel of the first sub-pixels of the first substrate, a first anode disposed in the first sub-pixel of the first substrate and connected to the first thin film transistor, a second anode disposed in a second sub-pixel of the second sub-pixels of the first substrate and connected to the second thin film transistor, a first emission part disposed on the first anode, a second emission part disposed on the second anode and a cathode disposed on the first emission part and the second emission part.

### CROSS-REFERENCE TO RELATED APPLICATIONS

This application claims the benefit of and priority to Korean Patent Application No. 10-2022-0176878 filed on Dec. 16, 2022 in the Korean Intellectual Property Office, the entirety of which is hereby incorporated herein by reference for all purposes as if fully set forth herein.

### BACKGROUND

### Technical Field

The present disclosure relates to a display apparatus.

### Description of the Related Art

Recently, with the development of various portable electronic apparatuses such as mobile communication terminals and notebook computers, a demand for display apparatuses applicable thereto is increasing.

The display apparatuses such as a liquid crystal display apparatus, a field emission display apparatus, an organic light emitting diode display apparatuses, an inorganic light emitting diode display apparatus, and the like are being studied. Among these display apparatuses, the application fields of electroluminescent display apparatuses including organic light emitting diode display apparatuses and inorganic light emitting diode display apparatuses are expanding due to the development of mass production technology, ease of driving parts, low power consumption, high image quality, realization of a large screen, and flexibility.

The electroluminescent display apparatus includes a plurality of pixels in a matrix form, and each of the plurality of pixels has three or more sub-pixels and includes one or more thin film transistors (TFT) that individually controls each of the sub-pixels in the pixel.

### BRIEF SUMMARY

Electroluminescent display apparatuses can be commercialized in various sizes, such as ultra-fine sizes or super-large sizes, in response to various needs of users. The electroluminescent display apparatuses known until recently can display in only one direction. Thus, in a case in which a display in both directions is required, it is proposed a method for performing dual display by adding two display panels, or a method for displaying a same image in both directions through left and right inversion by implementing the panel in a transparent form.

The disclosure is directed to display apparatuses capable of displaying different images on both surfaces.

The inventors of the present disclosure have recognized the limitations described above and have conducted various studies and experiments to enable independent driving in both directions so as to perform different displays on top and bottom surfaces of one panel. Through various studies and experiments, a new display apparatus capable of independent driving in both directions of the panel was invented.

An aspect of the present disclosure is to provide a display apparatus capable of independent driving in both directions so as to perform different displays on top and bottom surfaces of a single panel.

Another aspect of the present disclosure is to provide a display apparatus in which an emission layer is formed by a solution process.

Accordingly, embodiments of the present disclosure are directed to an apparatus that substantially obviates one or more of the problems due to limitations and disadvantages of the related art.

Additional features, advantages, and aspects are set forth in part in the present disclosure and will also be apparent from the present disclosure or may be learned by practice of the inventive concepts provided herein. Other features, advantages, and aspects of the present disclosure may be realized and attained by the structure particularly pointed out in the present disclosure, or derivable therefrom, and the claims hereof as well as the appended drawings.

To achieve these and other aspects of the present disclosure, as embodied and broadly described herein, in one or more aspects, a display apparatus according to an example embodiment of the present disclosure may include a first substrate including a plurality of first sub-pixels and a plurality of second sub-pixels, a first thin film transistor and a second thin film transistor disposed in a first sub-pixel of the first sub-pixels of the first substrate, a first anode disposed in the first sub-pixel of the first substrate and connected to the first thin film transistor, a second anode disposed in a second sub-pixel of the second sub-pixels of the first substrate and connected to the second thin film transistor, a first emission part disposed on the first anode, a second emission part disposed on the second anode and a cathode disposed on the first emission part and the second emission part.

According to example embodiments of the present disclosure, there is an advantage in that a configuration for dual emission may be simplified by applying a pixel structure for top emission and bottom emission to one substrate. And thus, it is advantageous for thinning.

According to example embodiments of the present disclosure, since configurations of driving circuits or emission elements for top emission and bottom emission are performed in the same process, light emission can be displayed without adding a separate panel or forming emission elements multiple times. In addition, it is possible to display independent screens on both surfaces in response to a user's request. For example, simultaneous display on both surfaces is possible by independently driving top emission and bottom emission.

According to example embodiments of the present disclosure, large-area printing is possible by applying a soluble process using inkjet to the formation of emission elements, thereby allowing for process optimization. In addition, there is an advantage of panel enlargement.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing general description and the following detailed description of the present disclosure are example and explanatory and are intended to provide further explanation of the disclosure.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 illustrates a display apparatus according to an example embodiment of the present disclosure.

FIG. 2 illustrates a sub-pixel of the display apparatus of FIG. 1.

FIG. 3 illustrates an arrangement of top light emitting parts and bottom light emitting parts in the display apparatus according to an example embodiment of the present disclosure by way of example.

FIG. 4 illustrates a portion of a cross-sectional structure of the display apparatus of FIG. 3.

FIG. 5A illustrates a stacked structure of a top emission element of the display apparatus of FIG. 4.

FIG. 5B illustrates a stacked structure of a bottom emission element of the display apparatus of FIG. 4 as an example.

FIG. 6A illustrates a stacked structure of the top emission element of FIG. 4 as an example.

FIG. 6B illustrates a stacked structure of the bottom emission element of FIG. 4 as an example.

FIG. 7 illustrates the portion of the cross-sectional structure of the display apparatus of FIG. 4 in detail.

FIG. 8 illustrates an arrangement of top emission parts, bottom emission parts, and transmission parts in a display apparatus according to another example embodiment of the present disclosure.

FIG. 9 illustrates another arrangement of top emission parts, bottom emission parts, and transmission parts in a display apparatus according to another example embodiment of the present disclosure.

FIG. 10 illustrates a portion of a planar structure of the display apparatus of FIG. 8.

FIG. 11 illustrates a portion of a cross-sectional structure of the display apparatus of FIG. 8.

FIG. 12 illustrates a portion of a cross-sectional structure of a display apparatus according to another example embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference is now made in detail to embodiments of the present disclosure, examples of which may be illustrated in the accompanying drawings. In the following description, where a detailed description of relevant known functions or configurations may unnecessarily obscure aspects of the present disclosure, a detailed description of such known functions or configurations may be omitted for brevity. The progression of processing steps and/or operations described is an example, and the sequence of steps and/or operations is not limited to that set forth herein and may be changed, with the exception of steps and/or operations necessarily occurring in a particular order.

Advantages and features of the present disclosure, and implementation methods thereof are clarified through the following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to understand the inventive concepts fully without limiting the protected scope of the present disclosure.

The shapes, dimensions, areas, ratios, angles, numbers, and the like, which are illustrated in the drawings to describe various example embodiments of the present disclosure, are merely given by way of example. Therefore, the present disclosure is not limited to the illustrations in the drawings. Like reference numerals generally denote like elements throughout the specification, unless otherwise specified.

Where a term like “comprise,” “have,” “include,” “contain,” “constitute,” “made up of,” or “formed of,” is used, one or more other elements may be added unless a more limiting term, such as “only” or the like, is used. The terms and names used in the present disclosure are merely used to describe particular embodiments, and are not intended to limit the scope of the present disclosure. An element described in the singular form is intended to include a plurality of elements, and vice versa, unless the context clearly indicates otherwise.

The word “example” is used to mean serving as an example or illustration, unless otherwise specified. Embodiments are example embodiments. Aspects are example aspects. Any implementation described herein as an “example” is not necessarily to be construed as preferred or advantageous over other implementations.

In one or more aspects, an element, feature, or corresponding information (e.g., a level, range, dimension, size, or the like) is construed as including an error or tolerance range even where no explicit description of such an error or tolerance range is provided. An error or tolerance range may be caused by various factors (e.g., process factors, internal or external impact, noise, or the like). Further, the term “may” encompasses all the meanings of the term “can.”

In describing a positional relationship where the positional relationship between two parts is described, for example, using “on,” “over,” “under,” “above,” “below,” “beneath,” “near,” “close to,” “adjacent to,” “beside,” “next to,” or the like, one or more other parts may be located between the two parts unless a more limiting term, such as “immediate(ly),” “direct(ly),” or “close(ly),” is used. For example, where a structure is described as being positioned “on,” “over,” “under,” “above,” “below,” “beneath,” “near,” “close to,” “adjacent to,” “beside,” or “next to” another structure, this description should be construed as including a case in which the structures contact each other as well as a case in which one or more additional structures are disposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference, unless otherwise specified.

In describing a temporal relationship, for example when where the temporal order is described as, for example, “after,” “subsequent,” “next,” “before,” “preceding,” “prior to,” or the like, a case that is not consecutive or not sequential may be included unless a more limiting term, such as “just,” “immediate(ly),” or “direct(ly),” is used.

It will be understood that, although the terms “first,” “second,” or the like may be used herein to describe various elements, these elements should not be limited by these terms, for example, to any particular order, precedence, or number of elements. These terms are only used to distinguish one element from another. For example, a first element could be termed a second element, and, similarly, a second element could be termed a first element, without departing from the scope of the present disclosure. Furthermore, the first element, the second element, and the like may be arbitrarily named according to the convenience of those skilled in the art without departing from the scope of the present disclosure. The terms “first,” “second,” and the like may be used to distinguish components from each other, but the functions or structures of the components are not limited by ordinal numbers or component names in front of the components.

In describing the elements of the present disclosure, “first,” “second,” “A,” “B,” “(a),” “(b),” or the like may be used. These terms are intended to identify the corresponding element(s) from other element(s) and are not used to define the essence, basis, order, or number of the elements.

Where an element or layer is described as “coupled,” “connected,” “attached,” or “adhered” to another element or layer, the element or layer can not only be directly connected, coupled, attached, or adhered to another element or layer, but also be indirectly connected, coupled, attached, or adhered to another element or layer with one or more intervening elements or layers disposed or interposed between the elements or layers, unless otherwise specified.

The term “at least one” should be understood as including any and all combinations of one or more of the associated listed items. For example, the meaning of “at least one of a first item, a second item, and a third item” encompasses the combination of all three listed items, combination of any two of the first item, the second item, and the third item as well as any individual item, the first item, the second item, or the third item.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two.

In one or more aspects, the phrases “each other” and “one another” may be used interchangeably simply for convenience unless stated otherwise. For example, an expression “different from each other” may be understood as different from one another. In another example, an expression “different from one another” may be understood as different from each other. In one or more examples, the number of elements involved in the foregoing expression may be two. In one or more examples, the number of elements involved in the foregoing expression may be more than two.

In the present disclosure, examples of a display apparatus may include a narrow-sense display apparatus such as a quantum dot module, an organic light emitting diode (OLED) module or a liquid crystal module (LCM) having a display panel and a driver for driving the display panel. Also, examples of the display apparatus may include a set device (or a set apparatus) or a set electronic apparatus such as a notebook computer, a TV, a computer monitor, an equipment apparatus including an automotive apparatus or another type of apparatus for vehicles, or a mobile electronic device such as a smartphone or an electronic pad, which is a complete product (or a final product) including an LCM, an OLED module, and a QD module.

Therefore, in the present disclosure, examples of the display apparatus may include a narrow-sense display apparatus itself, such as an LCM, an OLED module, and a QD module, and a set device, which is a final consumer device or an application product including the LCM, the OLED module, and the QD module.

In some embodiments, an LCM, an OLED module, and a QD module including a display panel and a driver may be referred to as a narrow-sense display apparatus, and an electronic apparatus, which is a final product including an LCM, an OLED module, and a QD module may be referred to as a set device. For example, the narrow-sense display apparatus may include a display panel, such an LCM, an OLED module, or a QD module, and a source printed circuit board (PCB), which is a controller for driving the display panel. The set device may further include a set PCB, which is a set controller electrically connected to the source PCB to overall control the set device (or set apparatus).

A display panel applied to embodiments of the present disclosure may use any type of display panel, including a liquid crystal display panel, an organic light emitting diode (OLED) display panel, a quantum dot (QD) display panel, and an electroluminescent display panel. The display panel of the embodiment is not limited to a specific display panel capable of bezel bending with a flexible substrate for an organic light emitting diode (OLED) display panel and a lower back plate support structure. Also, a shape or a size of a display panel applied to a display apparatus according to these embodiments is not limited.

In an example where the display panel is the organic light emitting display panel, the display panel may include a plurality of gate lines, data lines, and pixels respectively provided in intersections of the gate lines and the data lines. Also, the display panel may include an array including a thin film transistor (TFT), which is an element for selectively applying a voltage to each of the pixels, a light emitting element layer on the array, and an encapsulation substrate or an encapsulation layer disposed on the array to cover the light emitting element layer. The encapsulation substrate may protect the TFT and the light emitting element layer from an external impact and may prevent water or oxygen from penetrating into the light emitting element layer. Also, a layer provided on the array may include an inorganic light emitting layer, for example, a nano-sized material layer, a quantum dot, or the like.

Features of various embodiments of the present disclosure may be partially or overall coupled to or combined with each other, and may be operated, linked, or driven together in various ways. Embodiments of the present disclosure may be carried out independently from each other, or may be carried out together in co-dependent or related relationship. In one or more aspects, the components of each apparatus according to various embodiments of the present disclosure are may be operatively coupled and configured.

Unless otherwise defined, the terms (including technical and scientific terms) used herein have the same meaning as commonly understood by one of ordinary skill in the art to which example embodiments belong. It should be further understood that terms, such as those defined in commonly used dictionaries, should be interpreted as having a meaning that is, for example, consistent with their meaning in the context of the relevant art and should not be interpreted in an idealized or overly formal sense, unless expressly defined otherwise herein.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. In addition, for convenience of description, a scale, dimension, size, and thickness of each of the elements illustrated in the accompanying drawings may be different from an actual scale, dimension, size, and thickness. Thus, embodiments of the present disclosure are not limited to a scale, dimension, size, or thickness illustrated in the drawings.

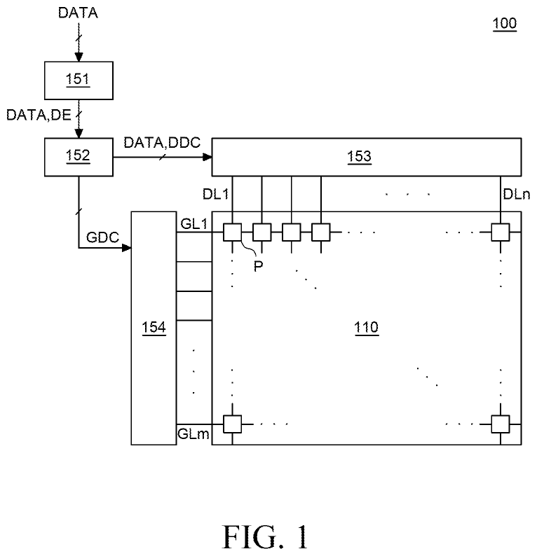

FIG. 1 is a block diagram of a display apparatus according to an example embodiment of the present disclosure.

Referring to FIG. 1, a display apparatus 100 according to an example embodiment of the present disclosure may include an image processor 151, a timing controller 152, a data driver 153, a gate driver 154, and a panel 110.

For example, the image processor 151 may output a data signal DATA and a data enable signal DE supplied from the outside. Also, the image processor 151 may output one or more of a vertical synchronization signal, a horizontal synchronization signal, and a clock signal in addition to the data enable signal DE.

The timing controller 152 may receive the data signal DATA together with the data enable signal DE or driving signals including the vertical synchronization signal, the horizontal synchronization signal, and the clock signal from the image processor 151. The timing controller 152 may output a gate timing control signal GDC for controlling an operation timing of the gate driver 154 and a data timing control signal DDC for controlling an operation timing of the data driver 153 based on the driving signals.

In addition, the data driver 153 may sample and latch the data signal DATA supplied from the timing controller 152 in response to the data timing control signal DDC supplied from the timing controller 152, and convert the data signal DATA into a gamma reference voltage to thereby output it.

For example, the data driver 153 may output the data signal DATA through data lines DL1 to DLn.

In addition, the gate driver 154 may output a gate signal while shifting a gate voltage level in response to the gate timing control signal GDC supplied from the timing controller 152.

For example, the gate driver 154 may output the gate signal through gate lines GL1 to GLm.

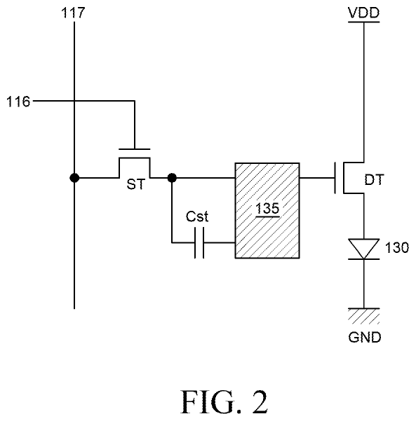

The panel 110 may display an image while sub-pixels P emit light in response to the data signal DATA and the gate signal supplied from the data driver 153 and the gate driver 154. A detailed structure of the sub-pixel P will be described in detail in FIG. 2 to FIG. 4.

FIG. 2 is a circuit diagram of a sub-pixel of the display apparatus of FIG. 1 according to an example embodiment of the present disclosure.

Referring to FIG. 2, one sub-pixel of the display apparatus according to an example embodiment of the present disclosure may include a switching transistor ST, a driving transistor DT, a compensation circuit 135, and an emission element 130.

The emission element 130 may operate to emit light according to a driving current formed by the driving transistor DT.

The switching transistor ST may perform a switching operation such that a data signal supplied through a data line 117 in response to a gate signal supplied through a gate line 116 is stored as a data voltage in a capacitor C_{ST}.

The driving transistor DT may operate such that a constant driving current flows between a high potential power line VDD and a low potential power line GND in response to the data voltage stored in the capacitor C_{ST}.

The compensation circuit 135 is a circuit for compensating for a threshold voltage or the like of the driving transistor DT, and the compensation circuit 135 may include one or more thin film transistors and capacitors. A configuration of the compensation circuit 135 may vary according to a compensation method.

It is illustrated that the sub-pixel illustrated in FIG. 2 is configured to have a 2T(Transistor)1C(Capacitor) structure including the switching transistor ST, the driving transistor DT, the capacitor C_{ST}, and the emission element 130. However, the sub-pixel may have various structures, such as 3T1C, 4T2C, 5T2C, 6T1C, 6T2C, 7T1C and 7T2C structures when the compensation circuit 135 is added thereto, and embodiments of the present disclosure are not limited thereto.

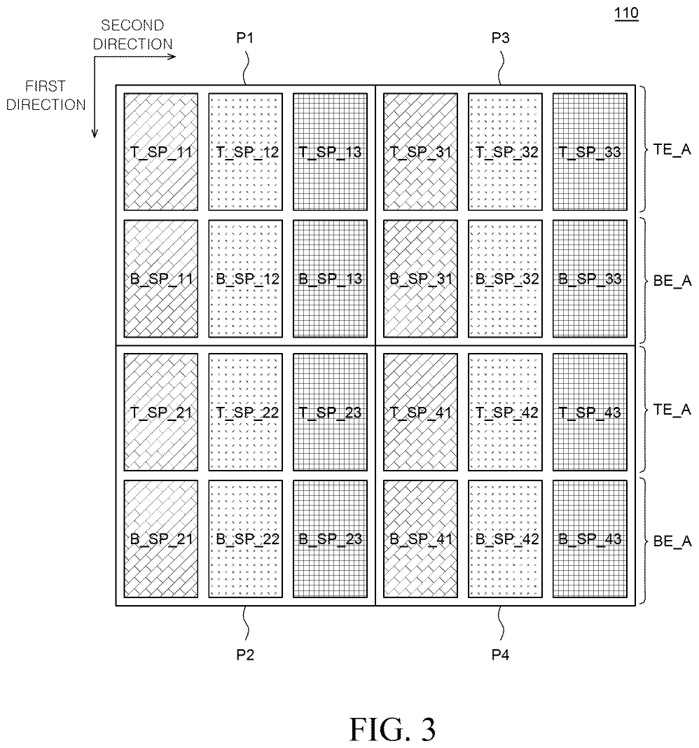

FIG. 3 illustrates an arrangement of top emission parts and bottom emission parts in the display apparatus according to an example embodiment of the present disclosure by way of example.

Although FIG. 3 illustrates an arrangement of 2×2 pixels P1, P2, P3, and P4 as an example for convenience of explanation, embodiments of the present disclosure are not limited thereto.

Referring to FIG. 3, the display apparatus according to an example embodiment of the present disclosure may implement respective sub-pixels T_SP_11, T_SP_12, T_SP_13, . . . , B_SP_11, B_SP_12, B_SP_13, . . . for top emission and bottom emission in the same panel 110. Accordingly, it is possible to realize a thinness of a light emitting display apparatus.

Further, the display apparatus according to an example embodiment of the present disclosure is capable of independently performing top emission and bottom emission, and thus, dual emission display may be simultaneously performed without interference.

Furthermore, the sub-pixels T_SP_11, T_SP_12, T_SP_13, . . . , B_SP_11, B_SP_12, B_SP_13, . . . for top emission and bottom emission are alternately disposed adjacent to each other row by row so that light emission is not biased to a specific position when light is emitted in respective directions. In addition, it is possible to emit light evenly over an entire area of the display apparatus, so uniform display apparatus is possible. When the sub-pixels for top emission and the sub-pixels for bottom emission are divided into large areas in the form of groups for respective emission directions, such as dividing the sub-pixels in a top and a bottom or a left and a right of the panel, they appear to be divided in half of the panel and displayed, so it is impossible to evenly use an entire area of the panel during top emission and bottom emission and thus, only a reduced image compared to a size of the panel will be displayed. However, in the display apparatus of the present disclosure, the sub-pixels T_SP_11, T_SP_12, T_SP_13, . . . , B_SP_11, B_SP_12, B_SP_13, . . . for top emission and bottom emission are alternately disposed adjacent to each other row by row, so that the sub-pixels T_SP_11, T_SP_12, T_SP_13, . . . for top emission and the sub-pixels B_SP_11, B_SP_12, B_SP_13, . . . for bottom emission may be disposed over the entire area of the panel. Thus, dual display is possible only with an area of the panel 110 provided. For example, the display apparatus of the present disclosure may be a dual display apparatus.

As described above, FIG. 3 illustrates an arrangement of four pixels P1, P2, P3, and P4 of 2×2 as an example.

Referring to FIG. 3, for example, a first pixel P1 and a second pixel P2 may be disposed adjacent to each other in a first direction, and a third pixel P3 and a fourth pixel P4 may also be disposed adjacent to each other in the first direction.

Also, for example, the first pixel P1 and the third pixel P3 may be disposed adjacent to each other in a second direction, and the second pixel P2 and the fourth pixel P4 may also be disposed adjacent to each other in the second direction.

For example, the first pixel P1 may include three sub-pixels T_SP_11, T_SP_12, and T_SP_13 for top emission that are disposed in a top emission sub-pixel area TE_A (for example, a sub-pixel area TE_A for top emission) and adjacent in the second direction, and three sub-pixels B_SP_11, B_SP_12, and B_SP_13 for bottom emission that are disposed in a bottom emission sub-pixel area BE_A (for example, a sub-pixel area BE_A for bottom emission) and adjacent in the second direction.

The top emission sub-pixel area TE_A may be referred to as a first sub-pixel area, and the bottom emission sub-pixel area BE_A may be referred to as a second sub-pixel area. Embodiments of the present disclosure are not limited thereto.

In the first pixel P1, the top emission sub-pixel area TE_A and the bottom emission sub-pixel area BE_A may be disposed adjacent to each other in the first direction.

In FIG. 3, a case in which three sub-pixels T_SP_11, T_SP_12, and T_SP_13 for top emission and three sub-pixels B_SP_11, B_SP_12, and B_SP_13 for bottom emission are disposed in the first pixel P1 is illustrated as an example, but embodiments of the present disclosure are not limited thereto. For example, when white sub-pixels are added, four sub-pixels for top emission and four sub-pixels for bottom emission may be respectively disposed in the first pixel P1.

For example, the sub-pixel T_SP_11 for top emission and the sub-pixel B_SP_11 for bottom emission in a first column of the first pixel PI may be red (R) sub-pixels. The sub-pixel T_SP_12 for top emission and the sub-pixel B_SP_12 for bottom emission in a second column of the first pixel P1 may be green (G) sub-pixels. The sub-pixel T_SP_13 for top emission and the sub-pixel B_SP_13 for bottom emission in a third column of the first pixel PI may be blue (B) sub-pixels, but embodiments of the present disclosure are not limited thereto.

For example, the second pixel P2 may include three sub-pixels T_SP_21, T_SP_22, and T_SP_23 for top emission that are disposed in the top emission sub-pixel area TE_A and adjacent in the second direction, and three sub-pixels B_SP_21, B_SP_22, and B_SP_23 for bottom emission that are disposed in the bottom emission sub-pixel area BE_A and adjacent in the second direction.

In the second pixel P2, the top emission sub-pixel area TE_A and the bottom emission sub-pixel area BE_A may be disposed adjacent to each other in the first direction.

In FIG. 3, a case in which three sub-pixels T_SP_21, T_SP_22, and T_SP_23 for top emission and three sub-pixels B_SP_21, B_SP_22, and B_SP_23 for bottom emission are disposed in the second pixel P2 is illustrated as an example, but embodiments of the present disclosure are not limited thereto, and when white sub-pixels are added, four sub-pixels for top emission and four sub-pixels for bottom emission may be respectively disposed in the second pixel P2.

For example, the sub-pixel T_SP_21 for top emission and the sub-pixel B_SP_21 for bottom emission in a first column of the second pixel P2 may be red (R) sub-pixels. The sub-pixel T_SP_22 for top emission and the sub-pixel B_SP_22 for bottom emission in a second column of the second pixel P2 may be green (G) sub-pixels. The sub-pixel T_SP_23 for top emission and the sub-pixel B_SP_23 for bottom emission in a third column of the second pixel P2 may be blue (B) sub-pixels, but embodiments of the present disclosure are not limited thereto.

For example, the third pixel P3 may include three sub-pixels T_SP_31, T_SP_32, and T_SP_33 for top emission that are disposed in the top emission sub-pixel area TE_A and are adjacent in the second direction and three sub-pixels B_SP_31, B_SP_32, and B_SP_33 for bottom emission that are disposed in the bottom emission sub-pixel area BE_A and adjacent in the second direction.

In FIG. 3, a case in which three sub-pixels T_SP_31, T_SP_32, and T_SP_33 for top emission and three sub-pixels B_SP_31, B_SP_32, and B_SP_33 for bottom emission are disposed in the third pixel P3 is illustrated as an example, but embodiments of the present disclosure are not limited thereto. For example, when white sub-pixels are added, four sub-pixels for top emission and four sub-pixels for bottom emission may be respectively disposed in the third pixel P3.

For example, the sub-pixel T_SP_31 for top emission and the sub-pixel B_SP_31 for bottom emission in a first column of the third pixel P3 may be red (R) sub-pixels. The sub-pixel T_SP_32 for top emission and the sub-pixel B_SP_32 for bottom emission in a second column of the third pixel P3 may be green (G) sub-pixels. The sub-pixel T_SP_33 for top emission and the sub-pixel B_SP_33 for bottom emission in a third column of the third pixel P3 may be blue (B) sub-pixels, but embodiments of the present disclosure are not limited thereto.

For example, the fourth pixel P4 may include three sub-pixels T_SP_41, T_SP_42, and T_SP_43 for top emission that are disposed in the top emission sub-pixel area TE_A and adjacent in the second direction and three sub-pixels B_SP_41, B_SP_42, and B_SP_43 for bottom emission that are disposed in the bottom emission sub-pixel area BE_A and adjacent in the second direction.

In FIG. 3, a case in which three sub-pixels T_SP_41, T_SP_42, and T_SP_43 for top emission and three sub-pixels B_SP_41, B_SP_42, and B_SP_43 for bottom emission are disposed in the fourth pixel P4 is illustrated as an example, but embodiments of the present disclosure are not limited thereto, and when white sub-pixels are added, four sub-pixels for top emission and four sub-pixels for bottom emission may be respectively disposed in the fourth pixel P4.

For example, the sub-pixel T_SP_41 for top emission and the sub-pixel B_SP_41 for bottom emission in a first column of the fourth pixel P4 may be red (R) sub-pixels. The sub-pixel T_SP_42 for top emission and the sub-pixel B_SP_42 for bottom emission in a second column of the fourth pixel P4 may be green (G) sub-pixels. The sub-pixel T_SP_43 for top emission and the sub-pixel B_SP_43 for bottom emission in a third column of the fourth pixel P4 may be blue (B) sub-pixels, but embodiments of the present disclosure are not limited thereto.

As described above, in the present disclosure, a case in which each of the first to fourth pixels P1, P2, P3, and P4 include a total of six sub-pixels including three sub-pixels T_SP_11, T_SP_12, T_SP_13, . . . for top emission and three sub-pixels B_SP_11, B_SP_12, B_SP_13, . . . for bottom emission is illustrated as an example, but embodiments of the present disclosure are not limited thereto.

In the present disclosure, thin film transistors and emission elements for driving in the sub-pixels T_SP_11, T_SP_12, T_SP_13, . . . for top emission and the sub-pixels B_SP_11, B_SP_12, B_SP_13, . . . for bottom emission may be formed together in the same panel 110, in particular, on one substrate of the panel 110. Therefore, compared to a structure of a related art dual display apparatus, the dual display apparatus of the present disclosure may allow for unification of the panel 110, and may be advantageous for thinning of the display apparatus.

Further, in the present disclosure, the thin film transistors and lines for driving in the sub-pixels T_SP_11, T_SP_12, T_SP_13, . . . for top emission and the sub-pixels B_SP_11, B_SP_12, B_SP_13, . . . for bottom emission may be disposed together in one sub-pixel area of one substrate, for example, the top emission sub-pixel area TE_A. Accordingly, since emission areas of the sub-pixels B_SP_11, B_SP_12, B_SP_13, . . . for bottom emission may be sufficiently secured, quality of bottom display may be improved.

In addition, in the present disclosure, during anode formation, a reflective electrode may be formed in the sub-pixels T_SP_11, T_SP_12, T_SP_13, . . . for top emission, and a transmissive electrode may be formed in the sub-pixels B_SP_11, B_SP_12, B_SP_13, . . . for bottom emission. For example, the sub-pixels T_SP_11, T_SP_12, T_SP_13, . . . for top emission may further include a reflective electrode in addition to a transmissive electrode.

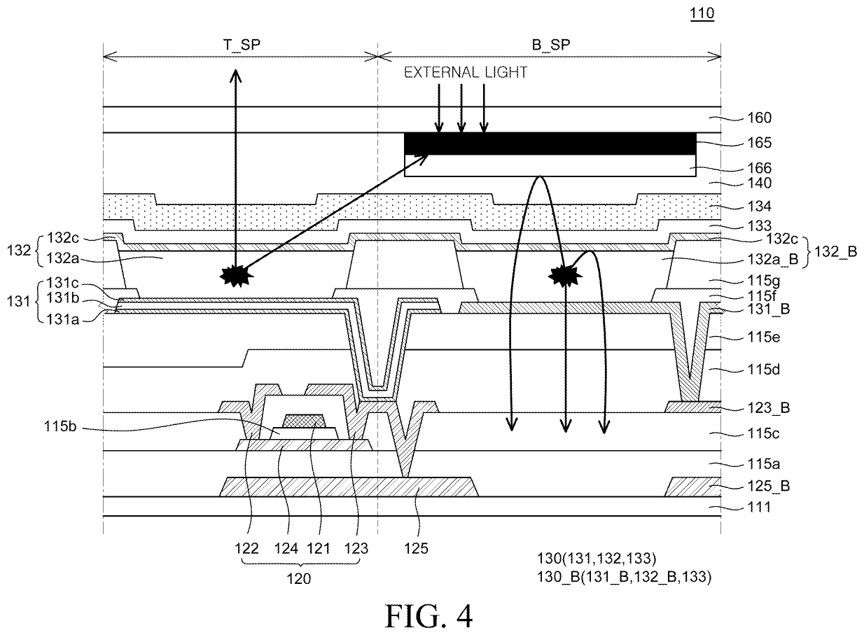

In addition, in the present disclosure, top emission elements may be formed in the sub-pixels T_SP_11, T_SP_12, T_SP_13, . . . for top emission, and bottom emission elements may be formed in the sub-pixels B_SP_11, B_SP_12, B_SP_13, . . . for bottom emission. A detailed description regarding this will be described later with reference to FIG. 4.

Also, in the present disclosure, a cathode may be formed as a translucent electrode equally in the sub-pixels T_SP_11, T_SP_12, T_SP_13, . . . for top emission and the sub-pixels B_SP_11, B_SP_12, B_SP_13, . . . for bottom emission.

In addition, in the present disclosure, in the sub-pixels B_SP_11, B_SP_12, B_SP_13, . . . for bottom emission, a black matrix and a reflective layer are additionally formed on a second substrate, which is an encapsulation substrate, so that light of the bottom emission element may be directed downward (or bottomward). Accordingly, luminance and display quality of the sub-pixels B_SP_11, B_SP_12, B_SP_13, . . . for bottom emission may be improved.

In addition, in the present disclosure, in forming the top emission element and the bottom emission element, it is possible to easily change a thickness of an organic material for each element by applying a solution process. For example, the solution process may be inkjet printing, and embodiments of the present disclosure are not limited thereto.

Hereinafter, structures of the sub-pixels T_SP_11, T_SP_12, T_SP_13 . . . for top emission and the sub-pixels B_SP_11, B_SP_12, B_SP_13 . . . for bottom emission aforementioned will be described in detail with reference to the following drawings.

FIG. 4 illustrates a portion of a cross-sectional structure of the display apparatus of FIG. 3 according to an example embodiment of the present disclosure.

FIG. 4 illustrates a cross-sectional structure of one sub-pixel T_SP for top emission and one sub-pixel B_SP for bottom emission in the display apparatus of FIG. 3 as an example.

Referring to FIG. 4, the display apparatus according to an example embodiment of the present disclosure may include a first substrate 111 that is divided into or including a plurality of the sub-pixels T_SP for top emission and a plurality of the sub-pixels B_SP for bottom emission, an anode 131 and an emission part 132 for top emission that are provided in the sub-pixel T_SP for top emission, an anode 131_B and an emission part 132_B for bottom emission that are provided in the sub-pixel B_SP for bottom emission, a cathode 133 provided in the sub-pixel T_SP for top emission and the sub-pixel B_SP for bottom emission, and a black matrix 165 and a reflective layer 166 provided on a second substrate 160 of the sub-pixel B_SP for bottom emission.

The sub-pixel T_SP for top emission may be a first sub-pixel and the sub-pixel B_SP for bottom emission may be a second sub-pixel, but embodiments of the present disclosure are not limited thereto. In addition, the anode 131 for top emission and the emission part 132 for top emission may be a first anode and a first emission part, respectively, and the anode 131_B for bottom emission and the emission part 132_B for bottom emission may be a second anode and a second emission part, respectively, but embodiments of the present disclosure are not limited thereto.

The first substrate 111 and the second substrate 160 facing the first substrate 111, and an adhesive layer 140 provided in FIG. 4 may be selectively formed as needed. For example, without the second substrate 160 and the adhesive layer 140, only an encapsulation configuration may be provided on an upper portion of the cathode 133. The encapsulation configuration may be a thin film, and embodiments of the present disclosure are not limited thereto. The second substrate 160 has a sealing function and may maintain flatness. In some cases, as described above, if sufficient sealing is possible with a thin film sealing configuration, it may be replaced by this.

When the adhesive layer 140 is provided, the adhesive layer 140 having a thickness sufficient to maintain a gap or flat gap between the first substrate 111 and the second substrate 160 by covering steps caused by components between the first substrate 111 and the second substrate 160 may be applied.

For example, the adhesive layer 140 may be disposed on at least an entirety of the sub-pixel T_SP for top emission and the sub-pixel B_SP for bottom emission, and the adhesive layer 140 may not be disposed in a pad portion or a circuit part outside the first substrate 111.

The panel 110 of the present disclosure has a configuration including two facing first substrate 111 and second substrate 160 and components between the first substrate 111 and the second substrate 160. In the present disclosure, thin film transistors 120 and the emission elements 130 and 130_B for driving the sub-pixels T_SP for top emission and the sub-pixels B_SP for bottom emission may be formed together in the same panel 110. Therefore, compared to a structure of the related art attachable dual display apparatus, the dual display apparatus of the present disclosure has an advantage capable of unification of the panel 110, and thus may be advantageous for thinning thereof.

As described above, the display apparatus of the present disclosure may further include the black matrix 165 and the reflective layer 166 on the second substrate 160 in the sub-pixel B_SP for bottom emission. Here, “on the second substrate 160” does not mean an upper portion of the second substrate 160 in terms of position, but means that components are disposed directly in contact with the second substrate 160, and in the drawings, means a direction in which the sub-pixel B_SP for bottom emission faces the first substrate 111, and thus the reflective layer 166 may contact the adhesive layer 140.

In the display apparatus of the present disclosure, one portions of the emission parts 132 and 132_B, for example, a common layer 132c and the cathode 133 are used in common while other portions 132a and 132a_B of the emission parts 132 and 132_B, and respective anodes, for example, the anode 131 for top emission and the anode 131_B for bottom emission, the black matrix 165, and the reflective layer 166 are separately formed, which configure emission directions of the emission parts 132 and 132_B.

Hereinafter, configurations of the sub-pixel T_SP for top emission and the sub-pixel B_SP for bottom emission will be described in detail. Here, configurations of the sub-pixel T_SP for top emission will be referred to as first configurations, and configurations of the sub-pixel B_SP for bottom emission will be referred to as second configurations.

The first substrate 111 may be divided into or may include the plurality of sub-pixels T_SP for top emission and the plurality of sub-pixels B_SP for bottom emission.

The first substrate 111 may support and protect components of the dual display apparatus disposed on the first substrate 111.

The flexible first substrate 111 may be formed of a flexible material having flexibility, such as plastic. The flexible first substrate 111 may be in the form of a film including one of a polyester-based polymer, a silicon-based polymer, an acrylic polymer, a polyolefin-based polymer, and a copolymer thereof, and embodiments of the present disclosure are not limited thereto.

A first light shielding pattern 125 and a second light shielding pattern 125_B may be disposed on the first substrate 111. For example, the first light shielding pattern 125 and the second light shielding pattern 125_B may be disposed in the sub-pixel T_SP for top emission, and a part of the second light shielding pattern 125_B may be disposed in the sub-pixel B_SP for bottom emission.

For example, some of components of the sub-pixel T_SP for top emission and the sub-pixel B_SP for bottom emission may be disposed in the sub-pixel B_SP for bottom emission, but most of the components may be disposed in the sub-pixel T_SP for top emission. For example, no component other than an insulating layer may be disposed in a path of light from the second emission element 132_B of the sub-pixel B_SP for bottom emission to a lower surface thereof.

The first light shielding pattern 125 may be disposed at a lower portion of or below a first semiconductor layer 124 to prevent leakage current generated when light is incident on the first semiconductor layer 124. Also, the second light shielding pattern 125_B may be disposed at a lower portion of or below a second semiconductor layer. The first light shielding pattern 125 may be a first light shielding layer, and embodiments of the present disclosure are not limited thereto. The second light shielding pattern 125_B may be a second light shielding layer, and embodiments of the present disclosure are not limited thereto.

For example, the first light shielding pattern 125 and the second light shielding pattern 125_B may be formed of a single layer or multilayer structure formed of any one of opaque metals such as aluminum (Al), nickel (Ni), chromium (Cr), tungsten (W), titanium (Ti), neodymium (Nd), molybdenum (Mo) and copper (Cu) or an alloy thereof, and embodiments of the present disclosure are not limited thereto.

A buffer layer 115a may be disposed on the first substrate 111 on which the first light shielding pattern 125 and the second light shielding pattern 125_B are disposed.

The buffer layer 115a may protect various electrodes and lines from impurities such as moisture, oxygen, alkali ions, and the like, introduced from the first substrate 111 or a lower portion of the first substrate, and can have a multilayer structure composed of a first buffer layer and a second buffer layer. However, embodiments of the present disclosure are not limited thereto. The buffer layer 115a may be formed of silicon oxide (SiOx), silicon nitride (SiNx), or a multilayer structure thereof. The buffer layer 115a may be omitted.

A first thin film transistor 120 and a second thin film transistor may be disposed on the buffer layer 115a.

The first thin film transistor 120 and the second thin film transistor may be driving transistors, and for convenience of explanation, FIG. 4 illustrates only the first thin film transistor 120 of the sub-pixel T_SP for top emission. For example, the second thin film transistor of the sub-pixel B_SP for bottom emission may also be disposed in the sub-pixel T_SP for top emission. Other switching transistors, sensing transistors, and compensation circuits may also be included in the display apparatus 100 of the present disclosure, and may be disposed in the sub-pixel T_SP for top emission.

The first thin film transistor 120 and the second thin film transistor, which are the driving transistors, may respectively transfer current transmitted through the power line by a signal received from the switching transistor to a first anode 131 and a second anode 131_B, and may respectively control light emission by the current transmitted to the first anode 131 and the second anode 131_B.

The first thin film transistor 120 may include a first gate electrode 121, the first semiconductor layer 124, a first source electrode 122, and a first drain electrode 123. In addition, the second thin film transistor (drain electrode thereof 123_B shown) may include a second gate electrode, the second semiconductor layer, a second source electrode, and a second drain electrode 123_B (shown in FIGS. 4, 11, and 12).

Each of the switching transistors may be turned on by a gate pulse supplied to the gate line, and transfer the data voltage supplied to the data line to the first gate electrode 121 and the second gate electrode of the first thin film transistor 120 and the second thin film transistor.

The first semiconductor layer 124 and the second semiconductor layer may be disposed on the buffer layer 115a.

The first semiconductor layer 124 and the second semiconductor layer may be formed of polysilicon (p-Si), and in this case, a predetermined region of first semiconductor layer 124 and the second semiconductor layer may be doped with impurities. In addition, the first semiconductor layer 124 and the second semiconductor layer may be formed of amorphous silicon (a-Si) or may be formed of various organic semiconductor materials such as pentacene or the like. For another example, the first semiconductor layer 124 and the second semiconductor layer may be formed of an oxide semiconductor.

The oxide semiconductor has excellent mobility and uniformity properties. The oxide semiconductor may be formed of a quaternary metal oxide such as an indium tin gallium zinc oxide (InSnGaZnO)-based material, a ternary metal oxide such as an indium gallium zinc oxide (InGaZnO)-based material, an indium tin zinc oxide (InSnZnO)-based material, an indium aluminum zinc oxide (InAlZnO)-based material, a tin gallium zinc oxide (SnGaZnO)-based material, an aluminum gallium zinc oxide (AlGaZnO)-based material, and a tin aluminum zinc oxide (SnAlZnO)-based material, a binary metal oxide such as an indium zinc oxide (InZnO)-based material, a tin zinc oxide (SnZnO)-based material, an aluminum zinc oxide (AlZnO)-based material, a zinc magnesium oxide (ZnMgO)-based material, a tin magnesium oxide (SnMgO)-based material, an indium oxide (InO)-based material, a tin oxide (SnO)-based material, an indium gallium oxide (InGaO)-based material, a zinc oxide (ZnO)-based material and an indium magnesium oxide (InMgO)-based material, or the like. Composition ratios and materials of the respective elements are not limited.

Each of the first semiconductor layer 124 and the second semiconductor layer may include a source region and a drain region including p-type or n-type impurities, and a channel region between the source region and the drain region, and may further include a low concentration-doped region between the source region and the drain region adjacent to the channel region, but embodiments of the present disclosure are not limited thereto.

The source region and the drain region are regions doped with a high concentration of impurities, and may be connected to the source electrode 122 and the drain electrode 123 of the thin film transistor 120, respectively.

As an impurity ion, the p-type impurity or n-type impurity may be used. The p-type impurity may be one of boron (B), aluminum (Al), gallium (Ga), and indium (In), and embodiments of the present disclosure are not limited thereto. The n-type impurity may be one of phosphorus (P), arsenic (As), and antimony (Sb), and embodiments of the present disclosure are not limited thereto.

The channel region may be doped with the n-type impurity or p-type impurity according to a thin film transistor structure of the NMOS or PMOS.

A gate insulating layer 115b may be disposed on the first semiconductor layer 124 and the second semiconductor layer. For example, the gate insulating layer 115c may be formed of an insulating inorganic material such as silicon oxide (SiOx) or silicon nitride (SiNx), or may be formed of an insulating organic material or the like, and embodiments of the present disclosure are limited thereto.

The first gate electrode 121 and the second gate electrode may be disposed on the gate insulating layer 115b. The first gate electrode 121 and the second gate electrode may be formed of various conductive materials such as magnesium (Mg), aluminum (Al), nickel (Ni), chromium (Cr), molybdenum (Mo), gold (Au), tungsten (W) or an alloy thereof, and embodiments of the present disclosure are not limited thereto.

An interlayer insulating layer 115c may be disposed on the first gate electrode 121 and the second gate electrode. The interlayer insulating layer 115c may be formed of silicon oxide (SiOx), silicon nitride (SiNx), or a multilayer structure thereof, and embodiments of the present disclosure are not limited thereto.

The first source electrode 122 and the second source electrode, and the first drain electrode 123 and the second drain electrode 123_B may be disposed on the interlayer insulating layer 115c.

The first source electrode 122 and the second source electrode, and the first drain electrode 123 and the second drain electrode 123_B may be composed of a single layer or multiple layers of a metallic material such as aluminum (Al), molybdenum (Mo), chromium (Cr), gold (Au), titanium (Ti), nickel (Ni), neodymium (Nd) or copper (Cu) which is a conductive metal, or an alloy thereof, but embodiments of the present disclosure are not limited thereto.

The second drain electrode 123_B is disposed in the sub-pixel T_SP for top emission. and a part of the second drain electrode 123_B may be disposed in the sub-pixel B_SP for bottom emission for connection to the second anode 131_B.

A protective layer may be disposed on the first thin film transistor 120 and the second thin film transistor configured as described above.

For example, the protective layer may be formed of an inorganic insulating layer such as silicon oxide (SiOx) or silicon nitride (SiNx), but embodiments of the present disclosure are not limited thereto.

The protective layer may block or prevent unnecessary electrical connections between components disposed above and below the protective layer and prevent contamination or damage from the outside. Based on configurations and characteristics of the first thin film transistor 120, the second thin film transistor, a first emission element 130 and a second emission element 130_B, the protective layer may be omitted.

For example, a first planarization layer 115d and a second planarization layer 115e may be disposed on the first thin film transistor 120 and the second thin film transistor.

For example, the first planarization layer 115d and the second planarization layer 115e may be formed of one or more materials among acrylic resin, epoxy resin, phenolic resin, polyamide-based resin, unsaturated polyester-based resin, polyimide-based resin, polyphenylene-based resin, benzocyclobutene resin, and polyphenylene sulfide-based resins, but embodiments of the present disclosure are not limited thereto.

The first emission element 130 including the first anode 131, a first emission part 132, and the cathode 133, and the second emission element 130_B including the second anode 131_B, a second emission part 132_B, and the cathode 133 may be disposed on the first planarization layer 115d and the second planarization layer 115e.

The first emission element 130 may be disposed in the sub-pixel T_SP for top emission, and the second emission element 130_B may be disposed in the sub-pixel B_SP for bottom emission.

The first anode 131 and the second anode 131_B may be disposed on the second planarization layer 115e.

For example, the first anode 131 and the second anode 131_B may be electrodes serving to supply holes to the first emission part 132 and the second emission part 132_B, respectively. The first anode 131 and the second anode 131_B may be connected to the first thin film transistor 120 and the second thin film transistor through contact holes in the first planarization layer 115d and the second planarization layer 115e, respectively.

The first anode 131 of the sub-pixel T_SP for top emission may further include a reflective layer 131b such that emitted light is reflected from the first anode 131 and is more smoothly emitted in a direction toward an upper portion where the cathode 133 is disposed.

For example, the first anode 131 may have a two-layer structure in which a transparent conductive layer formed of a transparent conductive material and a reflective layer are sequentially stacked, or a three-layer structure in which a transparent conductive layer 131a, a reflective layer 131b, and a transparent conductive layer 131c are sequentially stacked, and the reflective layer 131b may be silver (Ag) or an alloy including silver. Embodiments of the present disclosure are not limited thereto.

The second anode 131_B of the sub-pixel B_SP for bottom emission may be formed of a transparent conductive material such as indium tin oxide (ITO) or indium zinc oxide (IZO), but embodiments of the present disclosure are not limited thereto.

Banks 115f and 115g may be disposed on the first anode 131, the second anode 131_B, and the second planarization layer 115e.

In the present disclosure, the banks 115f and 115g may include a first bank 115f having hydrophilic and a second bank 115g having hydrophobic, but embodiments of the present disclosure are not limited thereto.

For example, the second bank 115g may be disposed on the first bank 115f.

The first bank 115f may improve adhesion between the first emission part 132 and the second emission part 132_B with a polymer material by a film having a hydrophilic interface property.

The second bank 115g may reduce adhesion between the first emission part 132 and the second emission part 132_B by a film having a hydrophobic interface property. Therefore, even if the polymer material is formed on an inclined surface of the second bank 115g, because it has poor bonding strength (or attaching strength) with the second bank 115g, it may flow down and be confined or disposed within the second bank 115g.

The first bank 115f and the second bank 115g partition areas that actually emit light, for example, emission areas, and surround the sub-pixels, for example, the sub-pixel T_SP for top emission and the sub-pixel B_SP for bottom emission.

For example, the first anode 131 and the second anode 131_B may be spaced apart from each other, and an upper surface of the second planarization layer 115e at a lower portion thereof may be exposed. In this case, the first bank 115f may cover one end (or a portion) of the first anode 131 and one end (or a portion) of the second anode 131_B and be disposed to be in contact with or adjoin the upper surface of the second planarization layer 115e exposed between the first anode 131 and the second anode 131_B.

For example, the first bank 115f and the second bank 115g of the emission area may be removed to expose portions of the first anode 131 and the second anode 131_B.

The first emission part 132 and the second emission part 132_B may be disposed between the first anode 131 and the cathode 133 and between the second anode 131_B and the cathode 133, respectively.

The first emission part 132 and the second emission part 132_B may serve to emit light, and include at least one layer of a hole injection layer HIL, a hole transport layer HTL, an emission layer, an electron transport layer ETL, and an electron injection layer EIL, and some of the components may be omitted according to a structure or characteristics of the panel 100. Here, as the emission layer, it is also possible to apply an electroluminescent layer and an inorganic emission layer.

The hole injection layer may be disposed on the first anode 131 and the second anode 131_B to facilitate hole injection.

The hole transport layer is disposed on the hole injection layer and may smoothly transfer holes to the emission layer.

The emission layer is disposed on the hole transport layer and may emit light of a specific color by including a material capable of emitting light of a specific color. In addition, the light emission material may be formed of a phosphorescent material or a fluorescent material.

An electron injection layer may be further disposed on the electron transport layer. The electron injection layer is an organic layer that facilitates electron injection from the cathode 133 and may be omitted depending on a structure and characteristics of the display apparatus.

In addition, in the case of further disposing an electron blocking layer and/or a hole blocking layer for blocking a flow of holes or electrons at a position adjacent to the emission layer, it is possible to prevent a phenomenon in which the electrons move from the emission layer when injected into the emission layer and pass through the hole transport layer adjacent thereto or a phenomenon in which the holes move from the emission layer when injected into the emission layer and pass through the electron transport layer adjacent thereto, and thus, luminous efficiency may be improved.

In the present disclosure, for example, a first layer 132a of the first emission part 132 may be formed in the sub-pixel T_SP for top emission and a second layer 132a_B of the second emission part 132_B may be formed in the sub-pixel B_SP for bottom emission, by a solution process.

For example, the first layer 132a and the second layer 132a_B may include a hole injection layer, a hole transport layer, and an emission layer, but are not limited thereto.

For example, the solution process may include inkjet printing, and embodiments of the present disclosure are not limited thereto.

The common layer 132c may be disposed on the first layer 132a and the second layer 132a_B in common with the first emission part 132 and the second emission part 132_B.

The common layer 132c may include an electron transport layer and an electron injection layer.

For example, the common layer 132c may be disposed on an entire surface of the first substrate 111 including an upper portion of the second bank 115g.

The first layer 132a and the second layer 132a_B may have different thicknesses. For example, the first layer 132a may have a first thickness suitable for light emission of the sub-pixel T_SP for top emission, and the second layer 132a_B may have a second thickness suitable for light emission of the sub-pixel B_SP for bottom emission. The first thickness may be relatively thicker than the second thickness, but embodiments of the present disclosure are not limited thereto.

The first emission element 130 includes the reflective layer 131b, and by a microcavity effect in which reflection between the first anode 131 including the reflective layer 131b and the cathode 133 repeatedly occurs, light is repeatedly reflected in a cavity between the first anode 131 and the cathode 133, thus, light efficiency may increase.

According to an example embodiment of the present disclosure, the first emission element 130 of the sub-pixel T_SP for top emission may have a different thickness for each sub-pixel, and the solution process may be more advantageous than a deposition process.

The cathode 133 may be commonly disposed on the first emission part 132 and the second emission part 132_B.

The cathode 133 serves to supply electrons to the first emission part 132 and the second emission part 132_B. Since the cathode 133 needs to supply electrons, it may be formed of a metal material such as magnesium or silver-magnesium, which is a conductive material having a low work function, but embodiments of the present disclosure are not limited thereto.

For example, the cathode 133 may be formed of a transflective metal of a silver alloy of Ag:Mg, but embodiments of the present disclosure are not limited thereto.

A capping layer 134 may be disposed on the cathode 133.

The capping layer 134 may serve to protect the emission elements 130 and 130_B while helping to efficiently emit light generated from the first emission part 132 and the second emission part 132_B to the outside. Also, the capping layer 134 may be omitted.

For example, the capping layer 134 may be formed of various organic compounds having a refractive index of 1.7 or more to prevent total reflection and loss of light traveling to the outside, but embodiments of the present disclosure are not limited thereto.

The adhesive layer 140 and the second substrate 160 may be disposed on the capping layer 134.

A protective layer may be further disposed on the capping layer 134.

The second substrate 160 may be an encapsulation substrate.

For example, the adhesive layer 140 may include a first adhesive layer for improving adhesion with lower components and a second adhesive layer that is a face seal adhesive serving as a moisture barrier.

The reflective layer 166 and the black matrix 165 may be further disposed on the second substrate 160 of the sub-pixel B_SP for bottom emission.

Referring to FIG. 4, the black matrix 165 may reduce reflection of external light by the reflective layer 166 when the sub-pixel T_SP for top emission is driven.

FIG. 4 illustrates a case where the reflective layer 166 is disposed on the black matrix 165 to contact the black matrix 165, but the present disclosure is not limited thereto, and the reflective layer 166 may be disposed on the protective or the capping layer 134.

By differentiating configurations of the sub-pixels T_SP for top emission and the sub-pixels B_SP for bottom emission as described above, it is possible to implement a dual display apparatus capable of being driven independently in both directions and perform different displays on top and bottom surfaces (or the upper or lower surfaces) of the panel 110.

For example, in the present disclosure, the respective thin film transistors 120 and lines for driving the sub-pixels T_SP for top emission and the sub-pixels B_SP for bottom emission may be provided together in the top emission sub-pixel areas. In this case, a step between layers is reduced due to an increase in density of lines under the first emission element 130 in the sub-pixel T_SP for top emission, and thus, a surface curvature of the first anode 131 may be reduced. Accordingly, it is possible to improve degradation in characteristics of the first emission element 130 due to the surface curvature of the anode 131.

Further, in the present disclosure, during anode formation, a reflective electrode may be formed in the sub-pixel T_SP for top emission, and a transmissive electrode may be formed in the sub-pixel B_SP for bottom emission. For example, the sub-pixel T_SP for top emission may further include the reflective layer 131b in addition to the transparent conductive layers 131a and 131c, and the sub-pixel B_SP for bottom emission may include the second anode 131_B formed of only a transparent conductive material.

Furthermore, in the present disclosure, the first emission element 130 for top emission may be formed in the sub-pixel T_SP for top emission, and the second emission element 130_B for bottom emission may be formed in the sub-pixel B_SP for bottom emission.

Furthermore, in the present disclosure, the cathode 133 may be formed as a translucent electrode equally in the sub-pixel T_SP for top emission and the sub-pixel B_SP for bottom emission.

Furthermore, in the present disclosure, the black matrix 165 and the reflective layer 166 are further formed on the second substrate 160 which is an encapsulation substrate in the sub-pixel B_SP for bottom emission, and thus, light of the second emission element 130_B for light emission may be directed downward (or bottomward).

Furthermore, in the present disclosure, in forming the top emission element and the bottom emission element, it is possible to easily change a thickness of an organic material for each element by applying a solution process of inkjet printing.

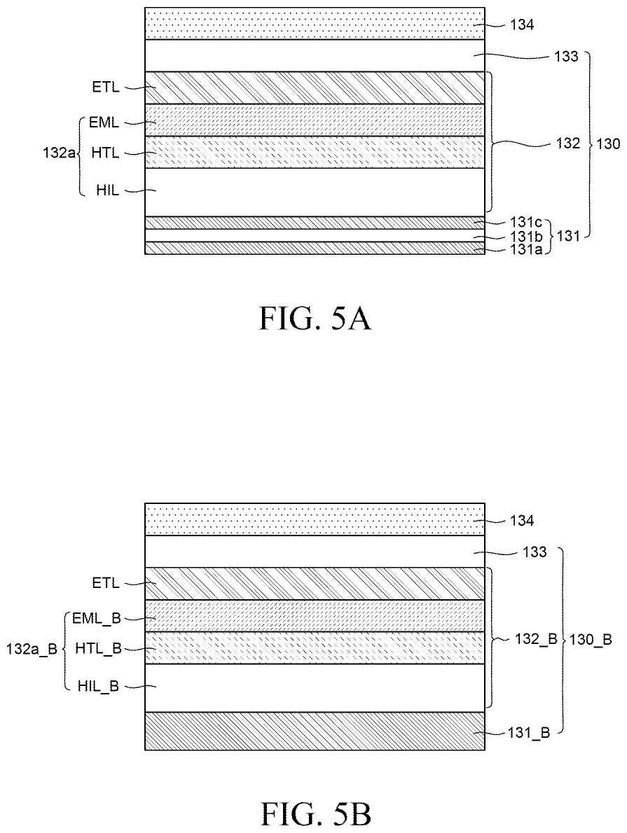

FIG. 5A illustrates a stacked structure of the top emission element of the display apparatus of FIG. 4.

FIG. 5B illustrates a stacked structure of the bottom emission element of the display apparatus of FIG. 4 as an example.

Hereinafter, configurations of the sub-pixels for top emission will be referred to as first configurations, and configurations of the sub-pixels for bottom emission will be referred to as second configurations.

Referring to FIG. 5A, the first emission element 130 may include, for example, the first anode 131, the first emission part 132, and the cathode 133.

Referring to FIG. 5B, the second emission element 130_B may include, for example, the second anode 131_B, the second emission part 132_B, and the cathode 133.

Referring to FIGS. 5A and 5B, the first emission element 130 may be disposed in the sub-pixel for top emission, and the second emission element 130_B may be disposed in the sub-pixel for bottom emission.

The first anode 131 and the second anode 131_B may be disposed on the second planarization layer.

For example, the first anode 131 of the sub-pixel for top emission may further include the reflective layer 131b such that emitted light is reflected from the first anode 131 and more smoothly emitted in a direction toward the upper portion thereof where the cathode 133 is disposed.

For example, the first anode 131 may have a two-layer structure in which a transparent conductive layer formed of a transparent conductive material and a reflective layer are sequentially stacked, or a three-layer structure in which the transparent conductive layer 131a, the reflective layer 131b, and the transparent conductive layer 131c are sequentially stacked, and embodiments of the present disclosure are not limited thereto. The three-layer structure may include, for example, ITO/Ag/ITO, but embodiments of the present disclosure are not limited thereto.

The second anode 131_B of the sub-pixel for bottom emission may be formed of a transparent conductive material such as indium tin oxide (ITO) or indium zinc oxide (IZO), but embodiments of the present disclosure are not limited thereto.

The first emission part 132 and the second emission part 132_B may be disposed on the first anode 131 and the second anode 131_B, respectively.

The first emission part 132 and the second emission part 132_B may emit light. For example, the first emission part 132 and the second emission part 132_B may include at least one layer of a hole injection layer HIL, a hole transport layer HTL, an electron blocking layer EBL, an emission layer, an electron transport layer ETL, a hole blocking layer HBL, and an electron injection layer EIL, and some of the components may be omitted according to a structure or characteristics of the panel. Embodiments of the present disclosure are not limited thereto.

A first hole injection layer HIL and a second hole injection layer HIL_B may be disposed on the first anode 131 and the second anode 131_B, respectively.

According to an example embodiment of the present disclosure, the first hole injection layer HIL and the second hole injection layer HIL_B may be individually formed in the sub-pixel for top emission and the sub-pixel for bottom emission, using a solution process.

For example, the first hole injection layer HIL and the second hole injection layer HIL_B may be formed of an aromatic conductive polymer including thiophene, sulfonate, or the like, or an aromatic amine-based material including alkyl, alkoxy or the like, but embodiments of the present disclosure are not limited thereto. For example, the aromatic conductive polymer may include poly(3,4-ethylenedioxythiophene) polystyrene sulfonate (PEDOT:PSS), but embodiments of the present disclosure are not limited thereto.

A first hole transport layer HTL and a second hole transport layer HTL_B may be disposed on the first hole injection layer HIL and the second hole injection layer HIL_B. respectively.

According to an example embodiment of the present disclosure, the first hole transport layer HTL and the second hole transport layer HTL_B may be individually formed in the sub-pixel for top emission and the sub-pixel for bottom emission, by a solution process. According to another example embodiment of the present disclosure, the first hole transport layer HTL and the second hole transport layer HTL_B may be formed by a deposition process. For example, the first hole transport layer HTL and the second hole transport layer HTL_B may be formed on the first hole injection layer HIL and the second hole injection layer HIL_B formed by a solution process. Accordingly, the first hole transport layer HTL and the second hole transport layer HTL_B may be formed according to shapes of the first hole injection layer HIL and the second hole injection layer HIL_B.

For example, the first hole transport layer HTL and the second hole transport layer HTL_B may be formed of amine-based materials including an aromatic ring such as carbazole, naphthalene, and fluorene, but embodiments of the present disclosure are not limited thereto. For example, the first hole transport layer HTL and the second hole transport layer HTL_B may include CBP (4,4′-N,N′-dicarbazole-biphenyl), NPD (N,N′-bis(1-naphthyl)-N,N′-diphenyl-1,1′-biphenyl-4,4′-diamine), TCTA (4-(9H-carbazol-9-yl)-N,N-bis[4-(9Hcarbazol-9-yl)phenyl]-benzenamine), and the like, but embodiments of the present disclosure are not limited thereto.

A first emission layer EML and a second emission layer EML_B may be disposed on the first hole transport layer HTL and the second hole transport layer HTL_B, respectively.

According to the example embodiment of the present disclosure, the first emission layer EML and the second emission layer EML_B may be individually formed in the sub-pixel for top emission and the sub-pixel for bottom emission, by a solution process. According to another example embodiment of the present disclosure, the first emission layer EML and the second emission layer EML_B may be formed by a deposition process. For example, the first emission layer EML and the second emission layer EML_B may be formed on the first hole injection layer HIL and the second hole injection layer HIL_B formed by a solution process. Accordingly, the first emission layer EML and the second emission layer EML_B may be formed according to shapes of the first hole injection layer HIL and the second hole injection layer HIL_B. According to another example embodiment of the present disclosure, the first hole injection layer HIL, the second hole injection layer HIL_B, the first hole transport layer HTL, and the second hole transport layer HTL_B may be formed by a solution process. In addition, the first emission layer EML and the second emission layer EML_B may be formed by a deposition process. Accordingly, the first emission layer EML and the second emission layer EML_B may be formed according to shapes of the first hole injection layer HIL and the second hole injection layer HIL_B.

The first emission layer EML and the second emission layer EML_B may emit light of a specific color by including a material capable of emitting light of a specific color. Further, the light emission material may be formed using a phosphorescent material or a fluorescent material.

The first emission layer EML and the second emission layer EML_B may be any one of a red emission layer, a green emission layer, and a blue emission layer. For example, in the case of a red sub-pixel, the first emission layer EML and the second emission layer EML_B may be red emission layers. In the case of a green sub-pixel, the first emission layer EML and the second emission layer EML_B may be green emission layers. In the case of a blue sub-pixel, the first emission layer EML and the second emission layer EML_B may be blue emission layers.

In the case of the red emission layer, it may be formed of an aromatic material including, for example, carbazole, fluorene, imidazole, and naphthalene, or the like, but embodiments of the present disclosure are not limited to thereto.

In the case of the green emission layer, it may be formed of a material having an aromatic structure including, for example, carbazole and fluorene, or the like, but embodiments of the present disclosure are not limited thereto.

In the case of the blue emission layer, it may be formed of a material having an aromatic structure including, for example, distyrylarylene, anthracene, and pyrene, or the like, but embodiments of the present disclosure are not limited thereto.

According to an example embodiment of the present disclosure, for example, the first hole injection layer HIL, the first hole transport layer HTL, and the first emission layer EML may be individually formed in the sub-pixels for top emission by a solution process. For example, the first hole transport layer HTL and the first emission layer EML may be formed according to a shape of the first hole injection layer HIL. The first hole injection layer HIL, the first hole transport layer HTL, and the first emission layer EML may be the first individual layer 132a of the first emission part 132.

Also, for example, the second hole injection layer HIL_B, the second hole transport layer HTL_B, and the second emission layer EML_B may be individually formed in the sub-pixel for bottom emission, by a solution process. For example, the second hole transport layer HTL_B and the second emission layer EML_B may be formed according to a shape of the second hole injection layer HIL_B. The second hole injection layer HIL_B, the second hole transport layer HTL_B, and the second emission layer EML_B may be the second individual layer 132a_B of the second emission part 132_B.

For example, the solution process may include inkjet printing, and embodiments of the present disclosure are not limited thereto.

The first individual layer 132a and the second individual layer 132a_B may have different thicknesses. For example, the first individual layer 132a may have a first thickness suitable for light emission of the sub-pixel for top emission, and the second individual layer 132a_B may have a second thickness suitable for light emission of the sub-pixel for bottom emission. The first thickness may be relatively thicker than the second thickness, but the present disclosure is not limited thereto. For example, a thickness of the first hole injection layer HIL formed in the first individual layer 132a by a solution process and a thickness of the second hole injection layer HIL_B formed in the second individual layer 132a_B by a solution process may be differently configured. Accordingly, the first individual layer 132a may have a thickness different from that of the second individual layer 132a_B.

The first emission elements 130 of the sub-pixels for top emission may have different thicknesses for the respective sub-pixels and thus a microcavity of the first emission element 130 may be adjusted, thereby improving luminous efficiency. Accordingly, the solution process may be more advantageous than the deposition process. For example, the first emission elements 130_B of the sub-pixels for bottom emission may have different thicknesses for the respective sub-pixels, and thus, a microcavity of the first emission element 130_B may be adjusted, thereby improving luminous efficiency. Accordingly, the solution process may be more advantageous than the deposition process.

For example, the electron transport layer ETL may be disposed as a common layer on the first individual layer 132a and the second individual layer 132a_B. However, embodiments of the present disclosure are not limited thereto, and an electron injection layer may be disposed as a common layer on the electron transport layer ETL.

For example, the electron transport layer ETL may be formed of an aromatic material including pyridine, triazine, oxadiazole, and triazole, but example embodiments of the present disclosure are not limited thereto. For example, the electron transport layer ETL may include 1,3,5-tris[(4′-tert-butylphenyl)-1,3,4-oxadiazoyl] benzene(1,3,5-Tris[(4′-tert-butylphenyl)-1,3,4-oxadiazoyl] benzene; OXD), bathophenathroline (4,7-Diphenyl-1,10-phenanthroline; Bphen), and TXD, and embodiments of the present disclosure are not limited thereto.

Further, the cathode 133 and the capping layer 134 may be disposed as a common layer on the electron transport layer ETL.

For example, the cathode 133 may be formed of a transflective metal of a silver alloy of Ag:Mg, but embodiments of the present disclosure are not limited thereto.

As described in FIG. 4, a protective layer may be further disposed on the capping layer 134. The reflective layer 166 may be disposed on the protective layer. For example, the reflective layer 166 may be disposed between the protective layer and the adhesive layer 140. According to another example embodiment of the present disclosure, the adhesive layer 140 may be disposed on the protective layer, and the reflective layer 166 may be disposed on the adhesive layer 140. For example, the reflective layer 166 may be disposed between the adhesive layer 140 and the black matrix 165. For example, the reflective layer 166 may be applied to the sub-pixel for top emission and the sub-pixel for bottom emission, in the same structure.

Embodiments of the present disclosure are not limited to an emission element structure using one stack, for example, one emission part, and can also be applied to an emission element structure of a tandem configuration including a plurality of emission parts to implement improved efficiency and lifespan characteristics.

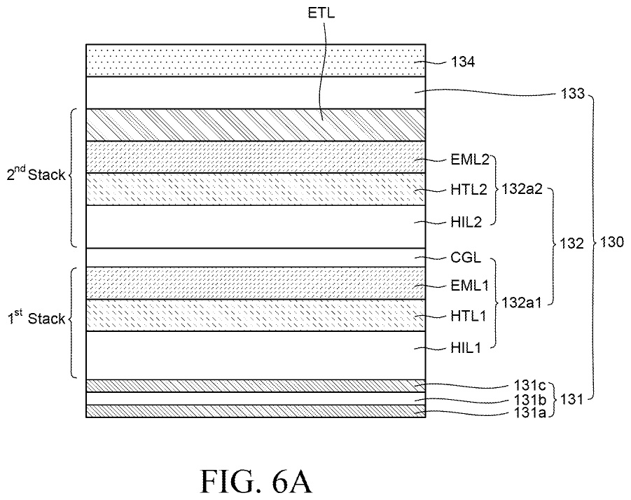

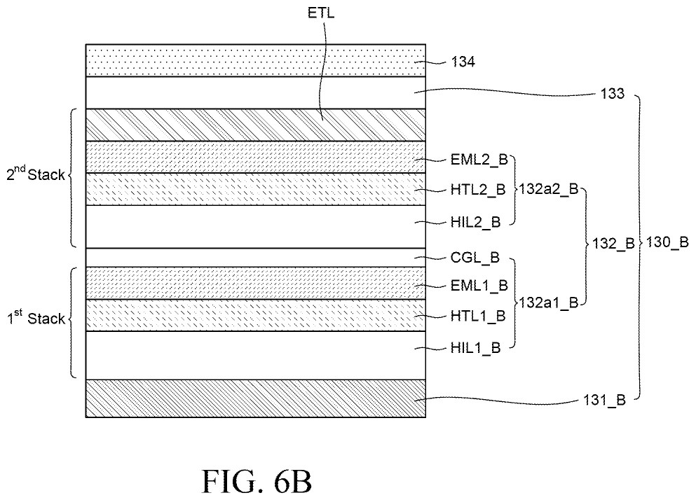

FIG. 6A illustrates a stacked structure of the top emission element of FIG. 4 as an example.

FIG. 6B illustrates a stacked structure of the bottom emission element of FIG. 4 as an example.

Hereinafter, configurations of the sub-pixels for top emission will be referred to as first configurations, and configuration of the sub-pixels for bottom emission will be referred to as second configurations.

Referring to FIG. 6A, the first emission element 130 may include, for example, the first anode 131, the first emission part 132, and the cathode 133.

Referring to FIG. 6B, the second emission element 130_B may include, for example, the second anode 131_B, the second emission part 132_B, and the cathode 133.

Referring to FIGS. 6A and 6B, the first emission element 130 may be disposed in the sub-pixel for top emission, and the second emission element 130_B may be disposed in the sub-pixel for bottom emission.

The first emission element 130 and the second emission element 130_B may have a tandem structure or a structure of a first emission part 1^{st} Stack and a second emission part 2^{nd} Stack. respectively, but embodiments of the present disclosure are not limited thereto.

Simply stacking and forming a plurality of emission parts does not increase light emission effects. In emitting light from a plurality of emission parts, the same effect as that of connecting the plurality of emission parts in series should be obtained.

A charge generation layer (CGL) CGL or CGL_B may be configured between a plurality of emission parts stacked to obtain an improved light emission effect by connecting a plurality of emission elements, for example, between the first emission part 1^{st} Stack and the second emission part 2^{nd} Stack. For example, the charge generation layers CGL and CGL_B may include an n-type charge generation layer and a p-type charge generation layer disposed between the first emission part 1^{st} Stack and the second emission part 2^{nd} Stack. However, embodiments of the present disclosure are not limited thereto.

For example, in the first emission element 130, the first emission part 1^{st} Stack may include a first hole injection layer HIL1, a first hole transport layer HTL1, and a first emission layer EML1, but embodiments of the present disclosure are not limited thereto.

Further, in the first emission element 130, the second emission part (or 2^{nd} Stack) may include a first hole injection layer HIL2, a first hole transport layer HTL2, a first emission layer EML2, and an electron transport layer ETL, but embodiments of the present disclosure are not limited thereto.

Also, for example, in the second emission element 130_B, the first emission part (or 1^{st} Stack) may include a second hole injection layer HIL1_B, a second hole transport layer HTL1_B. and a second emission layer EML1_B, but embodiments of the present disclosure are not limited thereto.

In addition, in the second emission element 130_B, the second emission part (or 2^{nd} Stack) may include a second hole injection layer HIL2_B, a second hole transport layer HTL2_B, a second emission layer EML2_B, and an electron transport layer ETL, but embodiments of the present disclosure are not limited thereto.

The first anode 131 and the second anode 131_B may be disposed on the second planarization layer.

For example, the first anode 131 of the sub-pixel for top emission may further include the reflective layer 131b such that emitted light is reflected from the first anode 131 and more smoothly emitted in a direction toward the upper portion thereof where the cathode 133 is disposed.

For example, the first anode 131 may have a two-layer structure in which a transparent conductive layer formed of a transparent conductive material and a reflective layer are sequentially stacked or formed, or a three-layer structure in which the transparent conductive layer 131a, the reflective layer 131b, and the transparent conductive layer 131c are sequentially stacked or formed, but embodiments of the present disclosure are not limited thereto.

The second anode 131_B of the sub-pixel for bottom emission may be formed of a transparent conductive material such as indium tin oxide (ITO) or indium zinc oxide (IZO), but embodiments of the present disclosure are not limited thereto.

The first emission part 132 and the second emission part 132_B may be disposed on the first anode 131 and the second anode 131_B, respectively.

The first emission part 132 and the second emission part 132_B may have a tandem structure or a structure of the first emission part (or 1^{st} Stack) and the second emission part (or 2^{nd} Stack), respectively.

The first emission part (or 1^{st} Stack) may be disposed on the first anode 131 and the second anode 131_B, respectively.

For example, the first hole injection layer HIL1 and the second hole injection layer HIL1_B may be disposed on the first anode 131 and the second anode 131_B, respectively. For example, the first hole transport layer HIL1 and the second hole injection layer HIL1_B may be formed of the same material as that described in FIGS. 5A and 5B, but embodiments of the present disclosure are not limited thereto.

According to an example embodiment of the present disclosure, the first hole injection layer HIL1 and the second hole injection layer HIL1_B may be individually formed in the sub-pixels for top emission by a solution process.

The first hole transport layer HTL1 and the second hole transport layer HTL1_B may be disposed on the first hole injection layer HIL1 and the second hole injection layer HIL1_B. respectively. For example, the first hole transport layer HTL1 and the second hole transport layer HTL1_B may be formed of the same material as that described in FIGS. 5A and 5B, but embodiments of the present disclosure are not limited thereto.

According to an example embodiment of the present disclosure, the first hole transport layer HTL1 and the second hole transport layer HTL1_B may be individually formed in the sub-pixel for top emission and the sub-pixel for bottom emission using a solution process. According to another example embodiment of the present disclosure, the first hole transport layer HTL1 and the second hole transport layer HTL1_B may be formed by a deposition process. For example, the first hole transport layer HTL1 and the second hole transport layer HTL1_B may be formed on the first hole injection layer HIL1 and the second hole injection layer HIL1_B formed by a solution process. Accordingly, the first hole transport layer HTL1 and the second hole transport layer HTL1_B may be formed according to shapes of the first hole injection layer HIL1 and the second hole injection layer HIL1_B.

The first emission layer EML1 and the second emission layer EML1_B may be disposed on the first hole transport layer HTL1 and the second hole transport layer HTL1_B. respectively.

The first emission layer EML1 and the second emission layer EML1_B may emit light of a specific color by including a material capable of emitting light of a specific color. The light emission material may be formed using a phosphorescent material or a fluorescent material.

The first emission layer EML1 and the second emission layer EML1_B may be any one of a red emission layer, a green emission layer, and a blue emission layer. For example, in the case of a red sub-pixel, the first emission layer EML1 and the second emission layer EML1_B may be red emission layers. In the case of a green sub-pixel, the first emission layer EML1 and the second emission layer EML1_B may be green emission layers. In the case of a blue sub-pixel, the first emission layer EML1 and the second emission layer EML1_B may be blue emission layers. For example, the first emission layer EML1 and the second emission layer EML1_B may be formed of the same material as that described in FIGS. 5A and 5B, but embodiments of the present disclosure are not limited thereto.

According to an example embodiment of the present disclosure, the first emission layer EML1 and the second emission layer EML1_B may be individually formed in the sub-pixel for top emission and the sub-pixel for bottom emission, by a solution process. According to another example embodiment of the present disclosure, the first emission layer EML1 and the second emission layer EML1_B may be formed by a deposition process. For example, the first emission layer EML1 and the second emission layer EML1_B may be formed on the first hole injection layer HIL1 and the second hole injection layer HIL1_B formed by a solution process. Accordingly, the first emission layer EML1 and the second emission layer EML1_B may be formed according to shapes of the first hole injection layer HIL1 and the second hole injection layer HIL1_B. According to another example embodiment of the present disclosure, the first hole injection layer HIL1, the second hole injection layer HIL1_B, the first hole transport layer HTL1, and the second hole transport layer HTL1_B may be formed by a solution process. In addition, the first emission layer EML1 and the second emission layer EML1_B may be formed by a deposition process. Accordingly, the first emission layer EML1 and the second emission layer EML1_B may be formed according to shapes of the first hole injection layer HIL1 and the second hole injection layer HIL1_B.

A first charge generation layer CGL and a second charge generation layer CGL_B may be disposed on the first emission layer EML1 and the second emission layer EML1_B. respectively.

According to an example embodiment of the present disclosure, the first charge generation layer CGL and the second charge generation layer CGL_B may be individually formed in the sub-pixel for top emission and the sub-pixel for bottom emission, by a solution process. According to another example embodiment of the present disclosure, the first charge generation layer CGL and the second charge generation layer CGL_B may be formed by a deposition process. For example, the first charge generation layer CGL and the second charge generation layer CGL_B may be formed on the first hole injection layer HIL1 and the second hole injection layer HIL1_B formed by a solution process. Accordingly, the first charge generation layer CGL and the second charge generation layer CGL_B may be formed according to shapes of the first hole injection layer HIL1 and the second hole injection layer HIL1_B. According to another example embodiment of the present disclosure, the first hole injection layer HIL1, the second hole injection layer HIL1_B. the first hole transport layer HTL1, the second hole transport layer HTL1_B, the first emission layer EML1, and the second emission layer EML1_B may be formed by a solution process, and the first charge generation layer CGL and the second charge generation layer CGL_B may be formed by a deposition process. Accordingly, the first charge generation layer CGL and the second charge generation layer CGL_B may be formed according to shapes of the first hole injection layer HIL1 and the second hole injection layer HIL1_B.

For example, the first charge generation layer CGL and the second charge generation layer CGL_B may include an n-type charge generation layer and a p-type charge generation layer. For example, the n-type charge generation layer may be formed of an organic layer where the material of the hole injection layer is doped with F4-TCNQ (2,3,5,6-tetrafluoro-7,7,8,8-tetracyano-quinodimethane), FeCl₃, FeF₃, and SbCl₅, but embodiments of the present disclosure are not limited thereto.

For example, the p-type charge generation layer may be formed of an organic layer where the material of the electron transport layer is doped with an alkali metal such as lithium (Li), sodium (Na), potassium (K), or cesium (Cs), or an alkaline earth metal such as magnesium (Mg), strontium (Sr), barium (Ba), or radium (Ra), but embodiments of the present disclosure are not limited thereto.

According to an example embodiment of the present disclosure, for example, the first hole injection layer HIL1, the first hole transport layer HTL1, the first emission layer EML1, and the first charge generation layer CGL may be individually formed in the sub-pixels for top emission by a solution process. The first hole injection layer HIL1, the first hole transport layer HTL1, the first emission layer EML1, and the first charge generation layer CGL may be the first individual layer 132a1 of the first emission part 132.

In addition, for example, the second hole injection layer HIL1_B, the second hole transport layer HTL1_B, the second emission layer EML1_B, and the second charge generation layer CGL_B may be individually formed in the sub-pixels for bottom emission, by a solution process. The second hole injection layer HIL1_B, the second hole transport layer HTL1_B, the second emission layer EML1_B, and the second charge generation layer CGL_B may be a second individual layer 132a1_B of the second emission part 132_B.

For example, the solution process may include inkjet printing, and embodiments of the present disclosure are not limited thereto.

The first individual layer 132a1 and the second individual layer 132a1_B may have different thicknesses. For example, the first individual layer 132a1 may have a first thickness suitable for light emission of sub-pixels for top emission, and the second individual layer 132a1_B may have a second thickness suitable for light emission of sub-pixels for bottom emission. The first thickness may be relatively thicker than the second thickness, but embodiments of the present disclosure are not limited thereto. For example, a thickness of the first hole injection layer HIL1 formed in the first individual layer 132a1 by a solution process and a thickness of the second hole injection layer HIL1_B formed in the second individual layer 132a1_B by a solution process may be differently formed. Accordingly, the first individual layer 132a1 may have a thickness different from that of the second individual layer 132a1_B.

The second emission part (or 2^{nd} Stack) may be disposed on each of the first and second individual layers 132a1 and 132a1_B. Since a description of the second emission part 2^{nd} Stack is substantially the same as that of the first emission part (or 1^{st} Stack), the description may be omitted or simplified.

For example, the first hole injection layer HIL2 and the second hole injection layer HIL2_B may be disposed on the first individual layer 132a1 and the second individual layer 132a1_B, respectively.

The first hole transport layer HTL2 and the second hole transport layer HTL2_B may be disposed on the first hole injection layer HIL2 and the second hole injection layer HIL2_B. respectively.

The first emission layer EML2 and the second emission layer EML2_B may be disposed on the first hole transport layer HTL2 and the second hole transport layer HTL2_B.

The first emission layer EML2 and the second emission layer EML2_B may emit light of a specific color by including a material capable of emitting light of a specific color. The light emitting material may be formed using a phosphorescent material or a fluorescent material.

The first emission layer EML2 and the second emission layer EML2_B may be any one of a red emission layer, a green emission layer, and a blue emission layer. For example, in the case of a red sub-pixel, the first emission layer EML2 and the second emission layer EML2_B may be red emission layers. In the case of a green sub-pixel, the first emission layer EML2 and the second emission layer EML2_B may be green emission layers, and in the case of a blue sub-pixel, the first emission layer EML2 and the second emission layer EML2_B may be blue emission layers.

According to an example embodiment of the present disclosure, for example, the first hole injection layer HIL2, the first hole transport layer HTL2, and the first emission layer EML2 may be individually formed in the sub-pixels for top emission, by a solution process. The first hole injection layer HIL2, the first hole transport layer HTL2, and the first emission layer EML2 may be a first individual layer 132a2 of the first emission part 132.

Also, for example, the second hole injection layer HIL2_B, the second hole transport layer HTL2_B, and the second emission layer EML2_B may be individually formed in the sub-pixels for bottom emission by a solution process. The second hole injection layer HIL2_B, the second hole transport layer HTL2_B, and the second emission layer EML2_B may be a second individual layer 132a2_B of the second emission part 132_B.

For example, the solution process may include inkjet printing, and embodiments of the present disclosure are not limited thereto.

The first individual layer 132a2 and the second individual layer 132a2_B may have different thicknesses. For example, the first individual layer 132a2 may have a first thickness suitable for light emission of sub-pixels for top emission, and the second individual layer 132a2_B may have a second thickness suitable for light emission of sub-pixels for bottom emission. The first thickness may be relatively thicker than the second thickness, but the present disclosure is not limited thereto. For example, a thickness of the first hole injection layer HIL1 formed in the first individual layer 132a1 by a solution process and a thickness of the second hole injection layer HIL1_B formed in the second individual layer 132a1_B by a solution process may be differently configured. Accordingly, the first individual layer 132a1 may have a thickness different from that of the second individual layer 132a1_B.

The first emission elements 130 of the sub-pixels for top emission may have different thicknesses for the respective sub-pixels and thus a microcavity of the first emission element 130 may be adjusted, thereby improving luminous efficiency. Accordingly, the solution process may be more advantageous than the deposition process. For example, the first emission elements 130_B of the sub-pixels for bottom emission may have different thicknesses for the respective sub-pixels, and thus, a microcavity of the first emission element 130_B may be adjusted, thereby improving luminous efficiency. Accordingly, the solution process may be more advantageous than the deposition process.

For example, the electron transport layer ETL may be disposed as a common layer on first individual layer 132a2 and second individual layer 132a2_B. However, embodiments of the present disclosure are not limited thereto, and an electron injection layer may be further disposed as a common layer on the electron transport layer ETL.

In addition, the cathode 133 and the capping layer 134 may be disposed as a common layer on the electron transport layer ETL.

As described in FIG. 4, a protective layer may be further disposed on the capping layer 134. The reflective layer 166 may be disposed on the protective layer. For example, the reflective layer 166 may be disposed between the protective layer and the adhesive layer 140. According to another example embodiment of the present disclosure, the adhesive layer 140 may be disposed on the protective layer, and the reflective layer 166 may be disposed on the adhesive layer 140. For example, the reflective layer 166 may be disposed between the adhesive layer 140 and the black matrix 165. For example, the reflective layer 166 may be applied to the sub-pixel for top emission and the sub-pixel for bottom emission, in the same structure.

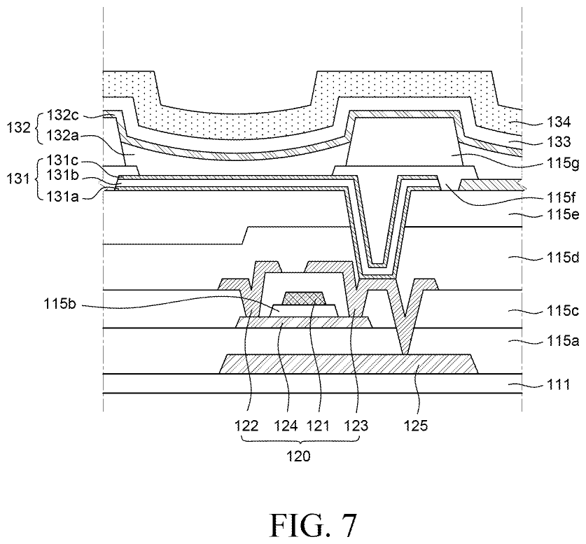

FIG. 7 illustrates the portion of the cross-sectional structure of the display apparatus of FIG. 4 in detail.

FIG. 7 illustrates a cross-sectional structure of the sub-pixel for top emission as an example in the cross-sectional structure of the display apparatus of FIG. 4, for convenience of explanation. In addition, FIG. 7 illustrates a stacked shape of the emission element in the cross-sectional structure of the sub-pixel for top emission in more detail.

Referring to FIG. 7, for example, the first emission element including the first anode 131, the first emission part 132, and the cathode 133 may be disposed on the second planarization layer 115e.

The first emission part 132 may be disposed between the first anode 131 and the cathode 133.

The first emission part 132 may emit light. For example, the first emission part 132 may include at least one among a hole injection layer HIL, a hole transport layer HTL, an emission layer, an electron transport layer ETL, and an electron injection layer EIL, and some of the components may be omitted depending on a structure or characteristics of the panel, and embodiments of the present disclosure are not limited thereto.

In the present disclosure, the first individual layer 132a of the first emission part 132 may be formed by, for example, a solution process.

For example, in the case of a single stack or one emission part, the first individual layer 132a may include a hole injection layer, a hole transport layer, and an emission layer, but embodiments of the present disclosure are not limited thereto.

Also, for example, in the case of a tandem structure, the first individual layer 132a may include a charge generation layer in addition to a hole injection layer, a hole transport layer, and an emission layer, but embodiments of the present disclosure are not limited thereto.

For example, the solution process may include inkjet printing, and embodiments of the present disclosure are not limited thereto.

For example, by the solution process, the first individual layer 132a is disposed in a shape in which a central portion is more concave than an edge (or a periphery) of the first individual layer 132a according to a shape of the first individual layer 132a in the emission area due to hydrophobicity of the second bank 115g within the emission area disposed by the first bank 115f and the second bank 115g. However, embodiments of the present disclosure are not limited thereto. For example, the first individual layer 132a may have a height lower than that of the second bank 115g.

The common layer 132c of the first emission part 132 may be disposed on the first individual layer 132a.

The common layer 132c may include an electron transport layer and an electron injection layer.

The common layer 132c may be formed by a deposition process.

For example, the common layer 132c may be formed on the entire surface of the first substrate 111 including the upper portion of the second bank 115g. For example, the common layer 132c may be formed according to the shape of the first individual layer 132a. For example, the common layer 132c may be formed in a shape in which a central portion is more concave than an edge (or a periphery) thereof according to the shape of the first individual layer 132a, in the emission area, but embodiments of the present disclosure are not limited thereto.

The cathode 133 may be commonly disposed on the first emission part 132.

The capping layer 134 may be disposed on the cathode 133.

For example, the cathode 133 and the capping layer 134 may be formed on the entire surface of the first substrate 111 over the first emission part 132. For example, the cathode 133 and the capping layer 134 may be formed according to the shape of the first individual layer 132a. For example, the cathode 133 and the capping layer 134 may be formed in a shape in which a central portion is more concave than an edge thereof according to the shape of the first individual layer 132a, in the emission area, but embodiments of the present disclosure are not limited thereto.

In the present disclosure, one pixel may further include a transparent sub-pixel in addition to the sub-pixel for top emission and the sub-pixel for bottom emission, which will be described in detail with reference to the drawings.

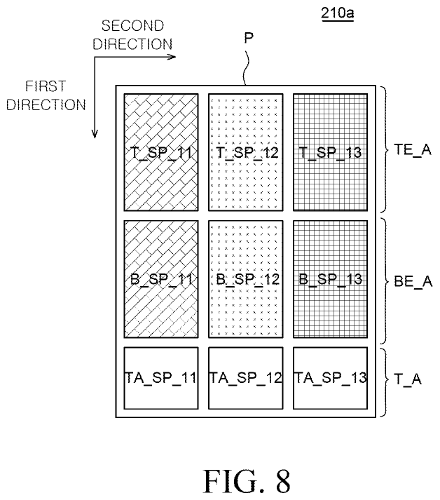

FIG. 8 illustrates an arrangement of top emission parts, bottom emission parts, and transmission parts in a display apparatus according to another example embodiment of the present disclosure.

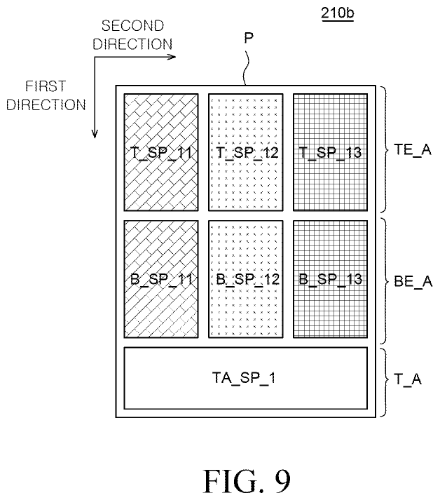

FIG. 9 illustrates another arrangement of top emission parts, bottom emission parts, and transmission parts in a display apparatus according to another example embodiment of the present disclosure.

The display apparatus according to another example embodiment of the present disclosure in FIGS. 8 and 9 further includes transparent sub-pixels compared to the display device according to an example embodiment of the present disclosure in FIG. 3, and other configurations thereof are substantially the same, and thus, repeated descriptions may be omitted.

A panel 210a of FIG. 8 illustrates an example in which three transparent sub-pixels TA_SP_11, TA_SP_12, and TA_SP_13 are disposed in one pixel P, and a panel 210b of FIG. 9 illustrates an example in which one transparent sub-pixel TA_SP_1 is disposed in one pixel P.

Although FIGS. 8 and 9 illustrate one pixel P for convenience of description, the description may be applied to adjacent pixels as in FIG. 3 described above.

Referring to FIGS. 8 and 9, the display apparatus according to another example embodiment of the present disclosure may implement the respective sub-pixels T_SP_11, T_SP_12, T_SP_13, B_SP_11, B_SP_12, and B_SP_13 for top emission and bottom emission and transparent sub-pixels TA_SP_11, TA_SP_12, TA_SP_13, and TA_SP_1 for transparent display in each of the same panels 210a and 210b. Accordingly, it is possible to realize the display apparatus having a thinness.

Further, the display apparatus according to another example embodiment of the present disclosure is capable of independently performing top emission and bottom emission, and thus, dual emission may be simultaneously performed without interference.

Furthermore, the sub-pixels T_SP_11, T_SP_12, T_SP_13, . . . , B_SP_11, B_SP_12, B_SP_13, . . . for top emission and bottom emission, and transparent sub-pixels TA_SP_11, TA_SP_12, TA_SP_13, and TA_SP_1 are alternately disposed adjacent to each other row by row so that light emission is not biased to a specific position when light is emitted in respective directions. Furthermore, it is possible to emit light evenly over an entire area of the display apparatus, so uniform display is possible.

As described above, FIGS. 8 and 9 illustrate an arrangement of one pixel P as an example.

Referring to FIGS. 8 and 9, for example, one pixel P may include three sub-pixels T_SP_11, T_SP_12, and T_SP_13 for top emission that are disposed in the sub-pixel area TE_A for top emission and adjacent in the second direction, and three sub-pixels B_SP_11, B_SP_12, and B_SP_13 for bottom emission that are disposed in the sub-pixel area BE_A for bottom emission and adjacent in the second direction. Further, one pixel P may further include three transparent sub-pixels TA_SP_11, TA_SP_12, and TA_SP_13 disposed in the transparent sub-pixel area T_A and adjacent in the second direction (in the case of FIG. 8) or one transparent sub-pixel TA_SP_1 (in the case of FIG. 9).

The top emission sub-pixel area TE_A may be a first sub-pixel area, the bottom emission sub-pixel area BE_A may be a second sub-pixel area, and the transparent sub-pixel area T_A may be a third sub-pixel area, and embodiments of the present disclosure are not limited thereto.

In one pixel P, the top emission sub-pixel area TE_A, the bottom emission sub-pixel area BE_A, and the transparent sub-pixel area T_A may be adjacent to one another in the first direction. For example, the top emission sub-pixel area TE_A and the bottom emission sub-pixel area BE_A may be adjacent to each other in the first direction, and the bottom emission sub-pixel area BE_A and the transparent sub-pixel area T_A may be adjacent to each other in the first direction. For example, the top emission sub-pixel area TE_A, the bottom emission sub-pixel area BE_A, and the transparent sub-pixel area T_A may be sequentially disposed in the first direction.

In FIG. 8, a case in which three sub-pixels T_SP_11, T_SP_12, and T_SP_13 for top emission, three sub-pixels B_SP_11, B_SP_12, and B_SP_13 for bottom emission, and three transparent sub-pixels TA_SP_11, TA_SP_12, and TA_SP_13 are disposed in one pixel P, is illustrated as an example. However, embodiments of the present disclosure are not limited thereto, and when white sub-pixels are added, four sub-pixels for top emission and four sub-pixels for bottom emission, and four transparent sub-pixels may be respectively disposed in one pixel P.

Further, in FIG. 9, a case in which three sub-pixels T_SP_11, T_SP_12, and T_SP_13 for top emission, three sub-pixels B_SP_11, B_SP_12, and B_SP_13 for bottom emission, and one transparent sub-pixel TA_SP_1 is disposed in one pixel P, is illustrated as an example. However, embodiments of the present disclosure are not limited thereto, and when white sub-pixels are added, four sub-pixels for top emission and four sub-pixels for bottom emission, and one transparent sub-pixel may be respectively disposed in one pixel P.

For example, the sub-pixel T_SP_11 for top emission, the sub-pixel B_SP_11 for bottom emission, and the transparent sub-pixel TA_SP_11 in a first column of one pixel P may be red (R) sub-pixels. The sub-pixel T_SP_12 for top emission, the sub-pixel B_SP_12 for bottom emission, and the transparent sub-pixel TA_SP_12 in a second column of the pixel P may be green (G) sub-pixels. The sub-pixel T_SP_13 for top emission, the sub-pixel B_SP_13 for bottom emission, and the transparent sub-pixel TA_SP_13 in a third column of the pixel P may be blue (B) sub-pixels, but embodiments of the present disclosure are not limited thereto.

Since each of the transparent sub-pixels TA_SP_11, TA_SP_12, TA_SP_13, and TA_SP_1 includes the transparent sub-pixel area T_A, the display apparatus may have a transparent structure. With the transparent sub-pixels TA_SP_11, TA_SP_12, TA_SP_13, and TA_SP_1, the display apparatus according to another example embodiment of the present disclosure may implement transparent display panels 210a and 210b and a transparent display apparatus.

In FIGS. 8 and 9, a case in which for example, heights of the respective transparent sub-pixels TA_SP_11, TA_SP_12, TA_SP_13, and TA_SP_1 are lower than heights of the sub-pixels T_SP_11, T_SP_12, and T_SP_13 for top emission and the sub-pixels B_SP_11 and B_SP_12, and B_SP_13 for bottom emission is illustrated as an example, but embodiments of the present disclosure are not limited thereto. For example, the heights of the respective transparent sub-pixels TA_SP_11, TA_SP_12, TA_SP_13, and TA_SP_1 may correspond to or be higher than the heights of the sub-pixels T_SP_11, T_SP_12, and T_SP_13 for top emission and the sub-pixels B_SP_11 and B_SP_12, and B_SP_13 for bottom emission. In addition, widths of the respective transparent sub-pixels TA_SP_11, TA_SP_12, and TA_SP_13 in FIG. 8 may be equal to widths of the sub-pixels T_SP_11, T_SP_12, and T_SP_13 for top emission and the sub-pixels B_SP_11 and B_SP_12, and B_SP_13 for bottom emission, but embodiments of the present disclosure are not limited thereto. For example, the widths of the respective transparent sub-pixels TA_SP_11, TA_SP_12, and TA_SP_13 in FIG. 8 may correspond to, be similar to, or may be narrower or wider than the widths of the sub-pixels T_SP_11, T_SP_12, and T_SP_13 for top emission and the sub-pixels B_SP_11 and B_SP_12, and B_SP_13 for bottom emission.

As a size of the transparent sub-pixel area T_A is larger than those of the top emission sub-pixel area TE_A and the bottom emission sub-pixel area BE_A, transparency of the transparent sub-pixels TA_SP_11, TA_SP_12, TA_SP_13, and TA_SP_1 may increase, and transparency of the transparent display apparatus may also be increased.

In another example embodiment of the present disclosure, in substantially the same manner as an example embodiment described above, thin film transistors, emission elements and the like for driving in the sub-pixels T_SP_11, T_SP_12, and T_SP_13 for top emission and the sub-pixels B_SP_11, B_SP_12, and B_SP_13 for bottom emission may be formed together in the same panels 210a and 210b, in particular, on one substrate among the same panels 210a and 210b. Therefore, compared to a structure of a related art dual display apparatus, the dual display apparatus of the present disclosure may allow for unification of the panels 210a and 210b, which may be advantageous for thinning of the display apparatus. Here, for example, the transparent sub-pixels TA_SP_11, TA_SP_12, TA_SP_13, and TA_SP_1 may not have thin film transistors, emission elements, and/or lines for driving.

Further, in the present disclosure, thin film transistors and lines for driving in the sub-pixels T_SP_11, T_SP_12, and T_SP_13 for top emission and the sub-pixels B_SP_11, B_SP_12, and B_SP_13 for bottom emission may be disposed together in one sub-pixel area of one substrate, for example, in the top emission sub-pixel area TE_A. Accordingly, since the emission areas of the sub-pixels B_SP_11, B_SP_12, and B_SP_13 for bottom emission may be sufficiently secured, quality of bottom display may be improved.

Furthermore, in the present disclosure, during anode formation, a reflective electrode may be formed in the sub-pixels T_SP_11, T_SP_12, and T_SP_13 for top emission, and a transmissive electrode may be formed in the sub-pixels B_SP_11, B_SP_12, and B_SP_13 for bottom emission. For example, the sub-pixels T_SP_11, T_SP_12, and T_SP_13 for top emission may further include a reflective electrode in addition to a transmissive electrode.

In addition, in the present disclosure, top emission elements may be formed in the sub-pixels T_SP_11, T_SP_12, and T_SP_13 for top emission, and bottom emission elements may be formed in the sub-pixels B_SP_11, B_SP_12, and B_SP_13 for bottom emission.

Also, in the present disclosure, a cathode may be as a translucent electrode equally in the sub-pixels T_SP_11, T_SP_12, and T_SP_13 for top emission, and the sub-pixels B_SP_11, B_SP_12, and B_SP_13 for bottom emission.

In addition, in the present disclosure, in the sub-pixels B_SP_11, B_SP_12, and B_SP_13 for bottom emission, a black matrix and a reflective layer are additionally formed on the second substrate, which is an encapsulation substrate, so that light of the bottom emission element may be directed downward (or bottomward). Accordingly, luminance and quality of the sub-pixels B_SP_11, B_SP_12, and B_SP_13 for bottom emission may be improved.

In addition, as described above, in the present disclosure, in forming the top emission element and the bottom emission element, it is possible to easily change a thickness of an organic material for each element by applying a solution process by inkjet printing.

Hereinafter, structures of the sub-pixels T_SP_11, T_SP_12, and T_SP_13 for top emission, the sub-pixels B_SP_11, B_SP_12, and B_SP_13 for bottom emission, and transparent sub-pixels TA_SP_11, TA_SP_12, TA_SP_13, and TA_SP_1 described above are described in detail with reference to the following drawings.

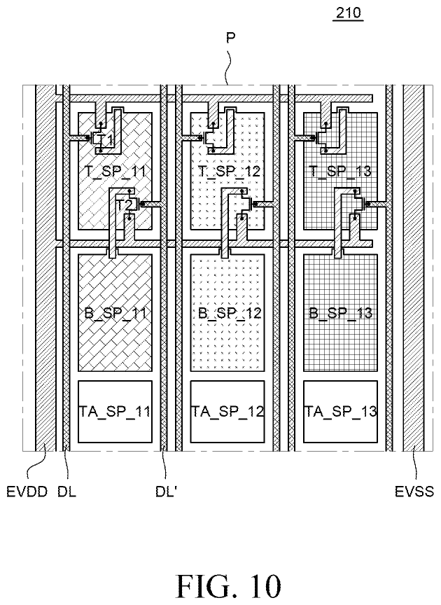

FIG. 10 illustrates a portion of a planar structure of the display apparatus of FIG. 8.

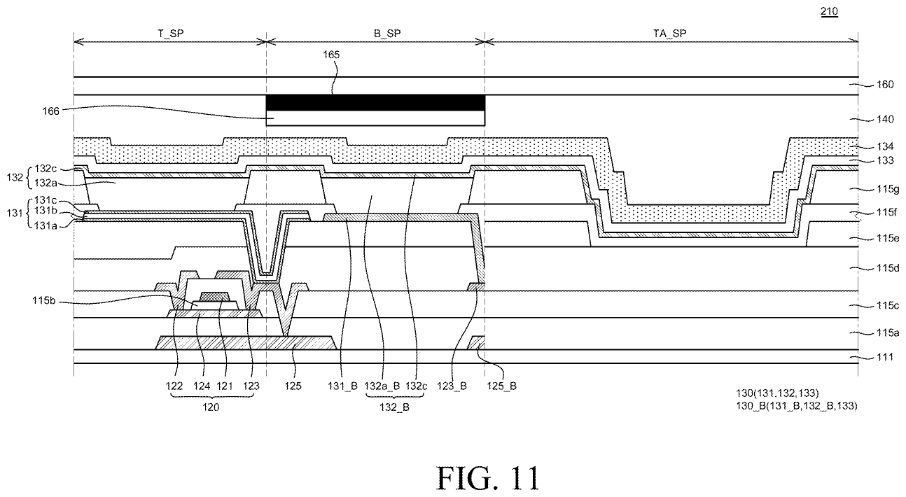

FIG. 11 illustrates a portion of a cross-sectional structure of the display apparatus of FIG. 8.

FIG. 10 illustrates, in the display apparatus of FIG. 8, a planar structure of one pixel P including, for example, three sub-pixels T_SP_11, T_SP_12, and T_SP_13 for top emission, three sub-pixels B_SP_11, B_SP_12, and B_SP_13 for bottom emission, and three transparent sub-pixels TA_SP_11, TA_SP_12, and TA_SP_13, as an example.

In addition, in FIG. 10, for convenience of description, illustration of switching transistors other than the driving transistors T1 and T2, emission elements, and other components may be omitted.

FIG. 11 illustrates a cross-sectional structure of one sub-pixel T_SP for top emission, one sub-pixel B_SP for bottom emission, and one transparent sub-pixel TA_SP in the dual display apparatus of FIG. 8 as an example.

First of all, referring to FIG. 10, the panel 210 of the display apparatus of the present disclosure may include a display area (or an active area) including an emission area and a non-display area (or a non-active area) around the display area.

The sub-pixels T_SP_11, T_SP_12, and T_SP_13 for top emission, the sub-pixels B_SP_11, B_SP_12, and B_SP_13 for bottom emission, and the transparent sub-pixels TA_SP_11, TA_SP_12, and TA_SP_13 may be disposed in the display area, and the sub-pixels T_SP_11, T_SP_12, and T_SP_13 for top emission, the sub-pixels B_SP_11, B_SP_12, and B_SP_13 for bottom emission, and the transparent sub-pixels TA_SP_11, TA_SP_12, and TA_SP_13 may be disposed in alternating rows.

For example, when the three sub-pixels T_SP_11, T_SP_12, and T_SP_13 for top emission, the three sub-pixels B_SP_11, B_SP_12, and B_SP_13 for bottom emission, and the three transparent sub-pixels TA_SP_11, TA_SP_12, and TA_SP_13 illustrated in FIG. 10 constitute one pixel P, such pixels P may be repeatedly disposed in a matrix form in the display area.

For example, a plurality of data lines DL and DL′ and a plurality of scan lines that cross each other may be disposed in one pixel P.

For example, the plurality of data lines DL and DL′ may include first data lines DL and second data lines DL′ that are respectively disposed on left and right sides and both sides of the sub-pixels T_SP_11, T_SP_12, and T_SP_13 for top emission, the sub-pixels B_SP_11, B_SP_12, and B_SP_13 for bottom emission, and the transparent sub-pixels TA_SP_11, TA_SP_12, and TA_SP_13 in respective columns, and three pairs of data lines DL and DL′ may be disposed for one pixel P. However, embodiments of the present disclosure are not limited thereto.

For example, the first data lines DL may be electrically connected to the sub-pixels T_SP_11, T_SP_12, and T_SP_13 for top emission to transmit a first data signal, and the second data lines DL′ may also be electrically connected to the pixels B_SP_11, B_SP_12, and B_SP_13 for bottom emission to transmit a second data signal.

In one pixel P, one high potential power line EVDD may be disposed on one side of the one pixel P and one low potential power line EVSS may be disposed on the other side of the one pixel P.

In addition, the driving transistors T1 and T2 may include first driving transistors T1 for driving the sub-pixels T_SP_11, T_SP_12 and T_SP_13 for top emission and second driving transistors T2 for driving the sub-pixels B_SP_11, B_SP_12 and B_SP_13 for bottom emission.

In the present disclosure, both the first driving transistor T1 and the second driving transistor T2 may be disposed in the sub-pixels T_SP_11, T_SP_12, and T_SP_13 for top emission.

For example, the high potential power line EVDD may be electrically connected to each of the first driving transistors T1 and the second driving transistors T2 disposed in the sub-pixels T_SP_11, T_SP_12, and T_SP_13 for top emission. Also, for example, the low potential power line EVSS may be electrically connected to the cathode.

In the display apparatus of the present disclosure, for example, both a first controller including the first driving transistors Tl for driving the sub-pixels T_SP_11, T_SP_12, and T_SP_13 for top emission, and a second controller including the second driving transistors T2 for driving the sub-pixels B_SP_11, B_SP_12, and B_SP_13 for bottom emission are disposed in the sub-pixels T_SP_11, T_SP_12, and T_SP_13 for top emission, and may be respectively connected to first emission elements of the sub-pixels T_SP_11, T_SP_12, and T_SP_13 for top emission and second emission elements of the sub-pixels B_SP_11, B_SP_12, and B_SP_13 and may be driven independently.

Referring to FIG. 11, the display apparatus according to another example embodiment of the present disclosure may include the first substrate 111 that is divided into or includes a plurality of sub-pixels T_SP for top emission, a plurality sub-pixels B_SP for bottom emission, and a plurality of transparent sub-pixels TA_SP, the anode 131 and the emission part 132 for top emission that are provided in the sub-pixel T_SP for top emission, the anode 131_B and the emission part 132_B for bottom emission that are provided in the sub-pixel B_SP for bottom emission, the cathode 133 provided in the sub-pixel T_SP for top emission, the sub-pixel B_SP for bottom emission, and the transparent sub-pixel TA_SP and the black matrix 165 and the reflective layer 166 provided on the second substrate 160 of the sub-pixel B_SP for bottom emission.

The sub-pixel T_SP for top emission may be a first sub-pixel, the sub-pixel B_SP for bottom emission may be a second sub-pixel, and the transparent sub-pixel TA_SP may be a third sub-pixel, but Embodiments of the present disclosure are not limited thereto. In addition, the anode 131 and the emission part 132 for top emission may be a first anode and a first emission part, respectively, and the anode 131_B and the emission part 132_B for bottom emission may be a second anode and a second emission part, respectively. Embodiments of the present disclosure are not limited thereto.

The panel 210 of the present disclosure has a configuration including two facing first substrate 111 and second substrate 160 and components between the first substrate 111 and the second substrate 160. In the present disclosure, the thin film transistor 120 and the emission elements 130 and 130_B for driving the sub-pixel T_SP for top emission and the sub-pixel B_SP for bottom emission may be formed together in the same panel 210.

As described above, the dual display apparatus of the present disclosure may further include the black matrix 165 and the reflective layer 166 on the second substrate 160 of the sub-pixel B_SP for bottom emission.

In the display apparatus of the present disclosure, portions of the emission parts 132 and 132_B, for example, the common layer 132c and the cathode 133, are applied to all of the sub-pixel T_SP for top emission, the sub-pixel B_SP for bottom emission, and the transparent sub-pixels TA_SP, and other portions 132a and 132a_B of the emission parts 132 and 132_B, the first anode 131 and the second anode 131_B, and the black matrix 165 and the reflective layer 166 are separately formed so that emission directions of the emission parts 132 and 132_B may be defined.

Hereinafter, configurations of the sub-pixel T_SP for top emission, the sub-pixel B_SP for bottom emission, and the transparent sub-pixel TA_SP will be described in detail. Here, for convenience of explanation, configurations of the sub-pixels T_SP for top emission will be referred to as first configurations, and configurations of the sub-pixels B_SP for bottom emission will be referred to as second configurations. As described above, repeated descriptions of the same components may be omitted.

The first substrate 111 may be divided into the plurality of sub-pixels T_SP for top emission, the plurality of sub-pixels B_SP for bottom emission, and the plurality of transparent sub-pixels TA_SP.

The first light blocking pattern 125 and the second light blocking pattern 125_B may be disposed on the first substrate 111. For example, the first light blocking pattern 125 and the second light blocking pattern 125_B may be disposed in the sub-pixel T_SP for top emission, and a part of the second light blocking pattern 125_B may be disposed in the sub-pixel B_SP for bottom emission. The first light blocking pattern 125 may be a first light shielding pattern, a first light blocking layer, or a first light shielding layer, and embodiments of the present disclosure are not limited thereto. The second light blocking pattern 125_B may be a second light shielding pattern, a second light blocking layer, or a second light shielding layer, and embodiments of the present disclosure are not limited thereto.

For example, some of components of the sub-pixel T_SP for top emission and the sub-pixel B_SP for bottom emission may be disposed in the sub-pixel B_SP for bottom emission, but most of the components may be disposed in the sub-pixel T_SP for top emission. For example, no component other than an insulating layer may be disposed in a path of light from the second emission element 132_B of the sub-pixel B_SP for bottom emission to a lower surface thereof.

The first light blocking pattern 125 may be disposed at a lower portion or below the first semiconductor layer 124 to prevent leakage current generated when light is incident on the first semiconductor layer 124. Also, the second light blocking pattern 125_B may be disposed at a lower portion or below the second semiconductor layer.

The buffer layer 115a may be disposed on the first substrate 111 on which the first light blocking pattern 125 and the second light blocking pattern 125_B are disposed. The buffer layer 115a may be disposed on an entire surface of the transparent sub-pixel TA_SP, but is not limited thereto.

The first thin film transistor 120 and a second thin film transistor may be disposed on the buffer layer 115a.

The first thin film transistor 120 and the second thin film transistor may be driving transistors, and for convenience of description, FIG. 11 illustrates only the first thin film transistor 120 of the sub-pixel T_SP for top emission. For example, the second thin film transistor of the sub-pixel B_SP for bottom emission may also be disposed in the sub-pixel T_SP for top emission. Other switching transistors, sensing transistors, and compensation circuits may also be included in the display apparatus of the present disclosure, and may be disposed together in the sub-pixel T_SP for top emission.

As such, in the present disclosure, the respective thin film transistors 120 and lines for driving the sub-pixels T_SP for top emission and the sub-pixels B_SP for bottom emission may be disposed together in the sub-pixel areas for top emission. Accordingly, it is possible to further secure the bottom emission parts of the sub-pixels B_SP for bottom emission and the transparent area of the transparent sub-pixels TA_SP. The resolution of the panel 210 may be increased due to an increase in area of the bottom emission parts, and a transparent display may be smoothly realized by securing the transparent area.

The first semiconductor layer 124 and the second semiconductor layer may be disposed on the buffer layer 115a.

The gate insulating layer 115b may be disposed on the first semiconductor layer 124 and the second semiconductor layer.

The first gate electrode 121 and the second gate electrode may be disposed on the gate insulating layer 115b.

The interlayer insulating layer 115c may be disposed on the first gate electrode 121 and the second gate electrode. The interlayer insulating layer 115c may be disposed on the entire surface of the transparent sub-pixel TA_SP, but is not limited thereto.

The first source electrode 122 and the second source electrode, and the first drain electrode 123 and the second drain electrode 123_B may be disposed on the interlayer insulating layer 115c.

The second drain electrode 123_B is disposed in the sub-pixel T_SP for top emission, while a part of the second drain electrode 123_B may be disposed in the sub-pixel B_SP for bottom emission for connection to the second anode 131_B.

A protective layer may be disposed on the first thin film transistor 120 and the second thin film transistor configured as described above.

For example, the first planarization layer 115d and the second planarization layer 115e may be disposed on the first thin film transistor 120 and the second thin film transistor. The first planarization layer 115d may be disposed on the entire surface of the transparent sub-pixel TA_SP, but embodiments of the present disclosure are not limited thereto.

The first emission element 130 including the first anode 131, the first emission part 132 and the cathode 133 and the second emission element 130_B including the second anode 131_B. the second emission part 132_B and the cathode 133 may be disposed on the first planarization layer 115d and the second planarization layer 115c.

The first emission element 130 may be disposed in the sub-pixel T_SP for top emission, and the second emission element 130_B may be disposed in the sub-pixel B_SP for bottom emission.

The first anode 131 and the second anode 131_B may be disposed on the second planarization layer 115e.

The first anode 131 of the sub-pixel T_SP for top emission may further include the reflective layer 131b such that emitted light is reflected from the first anode 131 and more smoothly emitted in a direction toward an upper portion thereof where the cathode 133 is disposed.

For example, the first anode 131 has a two-layer structure in which a transparent conductive layer formed of a transparent conductive material and a reflective layer are sequentially stacked or formed, or a three-layer structure in which the transparent conductive layer 131a, the reflective layer 131b, and the transparent conductive layer 131c are sequentially stacked or formed, and the reflective layer 131b may be silver (Ag) or an alloy including silver. Embodiments of the present disclosure are not limited thereto.

On the other hand, the second anode 131_B of the sub-pixel B_SP for bottom emission may be formed of a transparent conductive material such as indium tin oxide (ITO) or indium zinc oxide (IZO), but embodiments of the present disclosure are not limited thereto.

The banks 115f and 115g may be disposed on the first anode 131, the second anode 131_B, and the second planarization layer 115e.

In the present disclosure, the banks 115f and 115g may include a first bank 115f having a hydrophilic and a second bank 115g having a hydrophobic, but embodiments of the present disclosure are not limited thereto.

For example, the second bank 115g may be disposed on the first bank 115f.

The first bank 115f and the second bank 115g partition areas that actually emit light, for example, emission areas, and surround the sub-pixels, for example, the sub-pixel T_SP for top emission and the sub-pixel B_SP for bottom emission.

For example, the first anode 131 and the second anode 131_B may be spaced apart from each other so that an upper surface of the second planarization layer 115e may be exposed. In this case, the first bank 115f may cover one end (or one side or one portion) of the first anode 131 and one end (or one side or one portion) of the second anode 131_B and be disposed to be in contact with the upper surface of the second planarization layer 115e exposed between the first anode 131 and the second anode 131_B. In addition, the first bank 115f may extend toward the transparent sub-pixel TA_SP and be disposed on the entire surface of the transparent sub-pixel TA_SP, but embodiments of the present disclosure are not limited thereto.

In the present disclosure, light transmittance may be increased by removing portions of the second planarization layer 115e and the second bank 115g in the transparent sub-pixel TA_SP, but embodiments of the present disclosure are not limited thereto. For example, only one of the second planarization layer 115e and the second bank 115g may be removed from the transparent sub-pixel TA_SP, and an entirety of the second planarization layer 115e and the second bank 115g may also be removed.

For example, the first bank 115f and the second bank 115g of the emission area of each of the sub-pixel T_SP for top emission and the sub-pixel B_SP for bottom emission may be removed to expose portions of the first anode 131 and the second anode 131_B.

The first emission part 132 and the second emission part 132_B may be disposed between the first anode 131 and the cathode 133 and between the second anode 131_B and the cathode 133, respectively.

In the present disclosure, for example, the first individual layer 132a of the first emission part 132 may be formed in the sub-pixel T_SP for top emission, and the second individual layer 132a_B of the second emission part 132_B may be formed in the sub-pixel B_SP for bottom emission, by a solution process.

For example, the first individual layer 132a and the second individual layer 132a_B may include a hole injection layer, a hole transport layer, and an emission layer, but embodiments of the present disclosure are not limited thereto.

The common layer 132c may be disposed on the first individual layer 132a and the second individual layer 132a_B in common with the first emission part 132 and the second emission part 132_B.

The common layer 132c may include an electron transport layer and an electron injection layer.

For example, the common layer 132c may be disposed on the entire surface of the first substrate 111 including the upper portion of the second bank 115g. The common layer 132c may also be disposed on the transparent sub-pixel TA_SP, but embodiments of the present disclosure are not limited thereto.

The cathode 133 may be commonly disposed on the first emission part 132 and the second emission part 132_B. The cathode 133 may also be disposed in the transparent sub-pixel TA_SP, but embodiments of the present disclosure are not limited thereto.

The capping layer 134 may be disposed on the cathode 133. The capping layer 134 may also be disposed on the transparent sub-pixel TA_SP, but embodiments of the present disclosure are not limited thereto.

The adhesive layer 140 and the second substrate 160 may be disposed on the capping layer 134.

A protective layer may be further disposed on the capping layer 134.

The reflective layer 166 and the black matrix 165 may be further disposed on the second substrate 160 of the sub-pixel B_SP for bottom emission.

FIG. 11 illustrates a case where the reflective layer 166 is disposed on the black matrix 165 to be in contact with the black matrix 165, but embodiments of the present disclosure are not limited thereto, and the reflective layer 166 may be disposed on the protective layer therebelow or the capping layer 134. This will be described in detail with reference to the drawings.

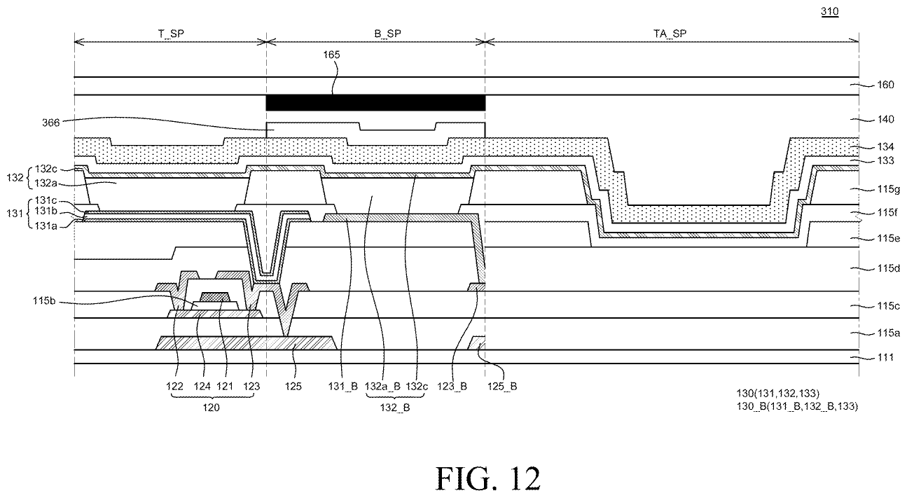

FIG. 12 illustrates a portion of a cross-sectional structure of a display apparatus according to another example embodiment of the present disclosure.

The display apparatus according to another example embodiment of the present disclosure in FIG. 12 is different from the display apparatus of another example embodiment of the present disclosure in FIG. 11 in terms of a configuration of a reflective layer 366, and other configurations thereof are substantially the same. Thus, repeated descriptions may be omitted.

FIG. 12 illustrates a cross-sectional structure of one sub-pixel T_SP for top emission, one sub-pixel B_SP for bottom emission, and one transparent sub-pixel TA_SP as an example.

In addition, in FIG. 12, illustration of the second thin film transistor of the sub-pixel B_SP for bottom emission, switching transistors and other components, other than the driving transistor of the sub-pixel T_SP for top emission, for example, the first thin film transistor 120, is omitted for convenience.

Referring to FIG. 12, a display apparatus according to another example embodiment of the present disclosure may include the first substrate 111 that is divided into the plurality of sub-pixels T_SP for top emission, the plurality of sub-pixels B_SP for bottom emission, and the plurality of transparent sub-pixels TA_SP, the anode 131 and the emission part 132 for top emission that are provided in the sub-pixel T_SP for top emission, the anode 131_B and the emission part 132_B for bottom emission that are provided in the sub-pixel B_SP for bottom emission, the cathode 133 provided in the sub-pixel T_SP for top emission, the sub-pixel B_SP for bottom emission, and the transparent sub-pixel TA_SP and the black matrix 165 and the reflective layer 366 provided in the sub-pixel B_SP for bottom emission.

A panel 310 of the present disclosure has a configuration including two facing first substrate 111 and second substrate 160 and components between the first substrate 111 and the second substrate 160. In the present disclosure, the thin film transistor 120 and the emission elements 130 and 130_B for driving the sub-pixel T_SP for top emission and the sub-pixel B_SP for bottom emission may be formed together in the same panel 310.

The display apparatus according to another example embodiment of the present disclosure may further include the black matrix 165 and the reflective layer 366 in the sub-pixel B_SP for bottom emission.

As described above, the adhesive layer 140 and the second substrate 160 may be disposed on the capping layer 134.

A protective layer may be further disposed on the capping layer 134.

In another example embodiment of the present disclosure, the reflective layer 366 may be disposed on the capping layer 134 or the protective layer of the sub-pixel B_SP for bottom emission. In addition, the black matrix 165 may be disposed on the second substrate 160 of the sub-pixel B_SP for bottom emission that faces the reflective layer 366.

When the reflective layer 366 is disposed on the capping layer 134 or the protective layer, a distance between the reflective layer 366 and the second emission element 130_B disposed therebelow decreases so that light emitted from the second emission element 130_B may be reflected downward without loss.

A display apparatus according to one or more embodiments of the present disclosure are described below.

A display apparatus according to one or more embodiments of the present disclosure may comprise a first substrate including a plurality of first sub-pixels and a plurality of second sub-pixels, a first thin film transistor and a second thin film transistor disposed in a first sub-pixel of the first sub-pixels of the first substrate, a first anode disposed in the first sub-pixels of the first substrate and connected to the first thin film transistor, a second anode disposed in a second sub-pixel of the second sub-pixels of the first substrate and connected to the second thin film transistor, a first emission part disposed on the first anode, a second emission part disposed on the second anode and a cathode disposed on the first emission part and the second emission part.

According to one or more embodiments of the present disclosure, the plurality of first sub-pixels and the plurality of second sub-pixels may be alternately disposed adjacent to each other row by row.

According to one or more embodiments of the present disclosure, the plurality of first sub-pixels and the plurality of second sub-pixels may be adjacent to each other in a first direction, the plurality of first sub-pixels may be disposed adjacent to each other in a second direction, and the plurality of second sub-pixels may be disposed adjacent to each other in the second direction.

According to one or more embodiments of the present disclosure, the first sub-pixel may be configured to display an image toward the cathode, and the second sub-pixel may be configured to display an image toward the first substrate.

According to one or more embodiments of the present disclosure, the first anode and the second anode may include a transparent conductive layer, and the first anode may further include a reflective layer.

According to one or more embodiments of the present disclosure, the cathode may be commonly disposed in the first sub-pixel and the second sub-pixel, and the cathode may include a transflective electrode.

According to one or more embodiments of the present disclosure, the display apparatus may further include a second substrate disposed on the cathode with an adhesive layer interposed therebetween.

According to one or more embodiments of the present disclosure, the display apparatus may further include a black matrix disposed on the second substrate facing the second sub-pixel and a reflective layer disposed on the black matrix.

According to one or more embodiments of the present disclosure, the display apparatus may further include a black matrix disposed on the second substrate facing the second sub-pixel and a reflective layer disposed on the cathode facing the black matrix.

According to one or more embodiments of the present disclosure, the display apparatus may further include a planarization layer disposed on the first thin film transistor and the second thin film transistor and a bank disposed on the first anode, the second anode, and the planarization layer.

According to one or more embodiments of the present disclosure, the bank may include a first bank having a hydrophilic material and a second bank having a hydrophobic material on the first bank.

According to one or more embodiments of the present disclosure, the first anode and the second anode may be spaced apart from each other, and a portion of an upper surface of the planarization layer is exposed. The first bank may cover one end of the first anode and one end of the second anode and may be in contact with the exposed upper surface of the planarization layer between the first anode and the second anode.

According to one or more embodiments of the present disclosure, the first emission part may include a first individual layer disposed in the first sub-pixel and a common layer disposed on the first individual layer.

According to one or more embodiments of the present disclosure, the second emission part may include a second individual layer disposed in the second sub-pixel and the common layer disposed on the second individual layer.

According to one or more embodiments of the present disclosure, the first individual layer may have a greater thickness than the second individual layer.

According to one or more embodiments of the present disclosure, the first individual layer and the second individual layer may be formed by a solution process.

According to one or more embodiments of the present disclosure, the first substrate may further include a plurality of third sub-pixels. The plurality of first sub-pixels, the plurality of second sub-pixels, and the plurality of third sub-pixels may be alternately disposed adjacent to one another row by row.

According to one or more embodiments of the present disclosure, the plurality of first sub-pixels, the plurality of second sub-pixels, and the plurality of third sub-pixels may be adjacent to one another in a first direction. The plurality of first sub-pixels may be adjacent to each other in a second direction. The plurality of second sub-pixels may be adjacent to each other in the second direction. The plurality of third sub-pixels may be adjacent to each other in the second direction.

According to one or more embodiments of the present disclosure, a first number of first sub-pixels among the plurality of first sub-pixels, the first number of second sub-pixels among the plurality of second sub-pixels, and the first number of third sub-pixels among the plurality of third sub-pixels may constitute a pixel. The pixel may further include a plurality of data lines and a plurality of scan lines disposed in the pixel.

According to one or more embodiments of the present disclosure, the plurality of data lines may include first data lines and second data lines disposed on both sides of the first sub-pixels, the second sub-pixels, and the third sub-pixels in respective columns.

According to one or more embodiments of the present disclosure, the first data lines may be electrically connected to the first sub-pixels and transmit a first data signal. The second data lines may be electrically connected to the second sub-pixels to transmit a second data signal that is the same as or different from the first data signal.

According to one or more embodiments of the present disclosure, the display apparatus may further include at least one high potential power supply line disposed on one side of the one pixel, and at least one low potential power supply line disposed on the other side of the one pixel.

According to one or more embodiments of the present disclosure, the high potential power line may be electrically connected to each of the first thin film transistor and the second thin film transistor.

According to one or more embodiments of the present disclosure, the display apparatus may further include a first planarization layer and a second planarization layer disposed on the first thin film transistor and the second thin film transistor and a bank disposed on the first anode, the second anode, and the first and second planarization layers. The bank may include a first bank having a hydrophilic material and a second bank having a hydrophobic material on the first bank.

According to one or more embodiments of the present disclosure, the first bank may extend to the third sub-pixel and may be disposed in an entire surface of the third sub-pixel. The second planarization layer and the second bank may be partially removed from the third sub-pixel.

It will be apparent to those skilled in the art that various modifications and variations can be made in the display apparatus of the present disclosure without departing from the scope of the present disclosure. Thus, it is intended that the present disclosure covers the modifications and variations of this disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a first substrate including a plurality of first sub-pixels and a plurality of second sub-pixels;
a first thin film transistor and a second thin film transistor disposed in a first sub-pixel of the first sub-pixels of the first substrate;
a first anode disposed in the first sub-pixel of the first substrate and connected to the first thin film transistor;
a second anode disposed in a second sub-pixel of the second sub-pixels of the first substrate and connected to the second thin film transistor;
a first emission part disposed on the first anode;
a second emission part disposed on the second anode; and
a cathode disposed on the first emission part and the second emission part.

2. The display apparatus of claim 1, wherein the plurality of first sub-pixels and the plurality of second sub-pixels are alternately disposed adjacent to each other row by row.

3. The display apparatus of claim 1, wherein the plurality of first sub-pixels and the plurality of second sub-pixels are adjacent to each other in a first direction,
wherein the plurality of first sub-pixels are disposed adjacent to each other in a second direction, and
wherein the plurality of second sub-pixels are disposed adjacent to each other in the second direction.

4. The display apparatus of claim 1, wherein the first sub-pixel is configured to display an image toward the cathode, and
wherein the second sub-pixel is configured to display an image toward the first substrate.

5. The display apparatus of claim 1, wherein the first anode and the second anode include a transparent conductive layer, and
wherein the first anode further includes a reflective layer.

6. The display apparatus of claim 1, wherein the cathode is commonly disposed in the first sub-pixel and the second sub-pixel, and
wherein the cathode includes a transflective electrode.

7. The display apparatus of claim 1, further comprising:
a second substrate disposed on the cathode with an adhesive layer interposed therebetween.

8. The display apparatus of claim 7, further comprising:
a black matrix disposed on the second substrate facing the second sub-pixel; and
a reflective layer disposed on the black matrix.

9. The display apparatus of claim 7, further comprising:
a black matrix disposed on the second substrate facing the second sub-pixel; and
a reflective layer disposed on the cathode facing the black matrix.

10. The display apparatus of claim 1, further comprising:
a planarization layer disposed on the first thin film transistor and the second thin film transistor; and
a bank disposed on the first anode, the second anode, and the planarization layer.

11. The display apparatus of claim 10, wherein the bank includes:
a first bank having a hydrophilic material; and
a second bank having a hydrophobic material on the first bank.

12. The display apparatus of claim 11, wherein the first anode and the second anode are spaced apart from each other, and a portion of an upper surface of the planarization layer is exposed, and
wherein the first bank covers one end of the first anode and one end of the second anode and is in contact with the exposed upper surface of the planarization layer between the first anode and the second anode.

13. The display apparatus of claim 1, wherein the first emission part includes:
a first individual layer disposed in the first sub-pixel; and
a common layer disposed on the first individual layer.

14. The display apparatus of claim 13, wherein the second emission part includes:
a second individual layer disposed in the second sub-pixel; and
the common layer disposed on the second individual layer.

15. The display apparatus of claim 14, wherein the first individual layer has a greater thickness than the second individual layer.

16. The display apparatus of claim 14, wherein the first individual layer and the second individual layer are formed by a solution process.

17. The display apparatus of claim 1, wherein the first substrate further includes a plurality of third sub-pixels, and
wherein the plurality of first sub-pixels, the plurality of second sub-pixels, and the plurality of third sub-pixels are alternately disposed adjacent to one another row by row.

18. The display apparatus of claim 17, wherein the plurality of first sub-pixels, the plurality of second sub-pixels, and the plurality of third sub-pixels are adjacent to one another in a first direction,
wherein the plurality of first sub-pixels are adjacent to each other in a second direction,
wherein the plurality of second sub-pixels are adjacent to each other in the second direction, and
wherein the plurality of third sub-pixels are adjacent to each other in the second direction.

19. The display apparatus of claim 17, wherein a first number of first sub-pixels among the plurality of first sub-pixels, the first number of second sub-pixels among the plurality of second sub-pixels, and the first number of third sub-pixels among the plurality of third sub-pixels constitute a pixel, and
wherein the pixel further includes a plurality of data lines and a plurality of scan lines disposed in the pixel.

20. The display apparatus of claim 19, wherein the plurality of data lines include first data lines and second data lines disposed on both sides of the first sub-pixels, the second sub-pixels, and the third sub-pixels in respective columns.

21. The display apparatus of claim 20, wherein the first data lines are electrically connected to the first sub-pixels and transmit a first data signal, and
wherein the second data lines are electrically connected to the second sub-pixels and transmit a second data signal that is the same as or different from the first data signal.

22. The display apparatus of claim 19, further comprising:
at least one high potential power supply line disposed on one side of the one pixel; and
at least one low potential power supply line disposed on the other side of the one pixel.

23. The display apparatus of claim 22, wherein the high potential power line is electrically connected to each of the first thin film transistor and the second thin film transistor.

24. The display apparatus of claim 17, further comprising:
a first planarization layer and a second planarization layer disposed on the first thin film transistor and the second thin film transistor; and
a bank disposed on the first anode, the second anode, and the first and second planarization layers,
wherein the bank includes:
a first bank having a hydrophilic material; and
a second bank having a hydrophobic material on the first bank.

25. The display apparatus of claim 24, wherein the first bank extends to a third sub-pixel and is disposed in an entire surface of the third sub-pixel, and
wherein the second planarization layer and the second bank are partially removed from the third sub-pixel.
